(19) United States
(12) Patent Application Publication
(10) Pub. No.: US 2022/0158015 A1
(43) Pub. Date: May 19, 2022

(54) SOLAR ARRAY MODULES FOR GENERATING ELECTRIC POWER

(71) Applicant: SOLARWAT LTD., Even Yehuda (IL)

(72) Inventors: Boris VATELMACHER, Ganei Tikva (IL); Gabi PAZ, Ganei Tikva (IL)

(73) Assignee: SOLARWAT LTD., Even Yehuda (IL)

(21) Appl. No.: 17/439,036

(22) PCT Filed: Mar. 18, 2020
(86) PCT No.: PCT/IL2020/050320

§ 371 Date: Sep. 14, 2021

Related U.S. Application Data
(60) Provisional application No. 62/819,718, filed on Mar. 18, 2019.
(60) Provisional application No. 62/940,893, filed on Nov. 27, 2019.
(60) Provisional application No. 62/966,028, filed on Jan. 27, 2020.

(51) Int. Cl. H01L 31/05

(52) U.S. Cl. CPC H01L 31/0504; H02J 2300/24

(57) ABSTRACT

A solar power generation module is provided for maximizing the power generated from the module and minimizing the power degradation inflicted by light obstructions. The module includes solar cells arranged in a matrix of N columns and M rows. At least one pair of neighboring rows of solar cells is mechanically and electrically interconnected by single wide polymer conductor stripe that extends over at least two adjacent columns of the at least one pair of neighboring rows. All solar cells in each pair of neighboring rows of a mutual string, are electrically interconnected in series by at least one respective thin wire conductor embedded inside the polymer conductor stripe. At least one solar cell in each string of solar cells is electrically interconnected in parallel to one or two solar cells, situated in a mutual row of an adjacent string, by a parallelly-connection conductive means.

### CROSS REFERENCE TO RELATED APPLICATIONS

This application is a national stage application of International Application Number PCT/IL2020/050320, which was filed on Mar. 18, 2020, which claims the benefit under 35 USC 119(e) from U.S. provisional application 62/819,718 filed Mar. 18, 2019, from U.S. provisional application 62/940,893 filed Nov. 27, 2019, and from U.S. provisional application 62/966,028 filed Jan. 27, 2020, the disclosures of which are included herein by reference.

### FIELD OF THE INVENTION

The present invention relates to solar array modules for generating electric-power and more particularly, to solar array modules facilitated to maximize the power generation from a solar module, configured to maximize the power generation from a plurality of solar cells by minimizing power degradation inflicted by light obstructions, interconnected in a matrix configuration using polymer conductor technology, such as polymer conductor technology.

### BACKGROUND AND PRIOR ART

Photovoltaic cells “referred to herein after also as “PV cells”, “PV solar cells”, “solar cells”, or simply as “cells”) have been widely used in a variety of applications to generate convenient electricity. Typically, a single solar cell produces an output voltage of around 0.5V, and a plurality of cells is conventionally connected in series to provide higher voltage levels. The solar cells are typically interconnected in solar-arrays, as described in PCT Published Application No. WO/2011/089607 filed on Jan. 23, 2011, as well as PCT Published Application No. WO/2018/142398, by the same inventor as the instant application and which is owned in common, which is hereby incorporated by reference in its entirety.

A number of individual photo-voltaic (PV) solar cells are electrical connected to each other to form a common solar-array module. The solar cells of a common solar-array module are electrically interconnected in series wherein the positive electrode (typically, with no limitations, the backside of the solar cell) is connected to the negative electrode of the solar cell (typically, with no limitations, the topside of the solar cell) of an adjacent cell.

The solar cells of a solar-array module are typically placed in a matrix of N columns and M rows. Since the cell voltage of an individual cell is of about 0.5 volts, a common solar-array module, having 60 solar cells arranged in a 6X10 matrix, yields a voltage of 30 volt and has a surface area of ˜1.6 m² (˜1 m×˜1.6 m).

It should be appreciated that the description above describes a typical PV module but other modes of interconnections and other numbers of solar cells in the module than that described above can be used. In a solar-array module, having a crisscross network configuration, all solar cells are also electrically interconnected in parallel, wherein each solar-array module includes a multiplicity of solar cells or cut sub-cells.

Reference is also made to FIG. 1, schematically showing an example solar-array module 30, including crisscross network configuration of solar cells 25. In this, example, solar-array module 30 includes 48 solar cells 25, arranged in m (8 in this example) columns (“strings 26” c₁-c₈) and n (6 in this example) rows (r₁-r₆), wherein each string 26 includes n solar cells 25, connected by parallel interconnections, forming a crisscross configuration.

The “crisscross” implementation relates to a previously described invention by the same inventor, published in PCT Published Application No. WO/2011/089607, which is hereby incorporated by reference as if fully described herein. A “crisscross” implementation is an electrical wiring configuration in which the electrical interconnections between cells are determined according to a regular grid pattern which interconnects all neighboring cells. By contrast, the presently claimed invention relates to electrical interconnections which are not necessarily determined according to a regular grid pattern.

A solar array module with crisscross configuration of the solar cells may consist of common 15.6 cm×15.6 cm PV solar cells or, for example, with no limitations, three times smaller sized PV solar cells (cut or fabricated solar sub-cells) 15.6 cm×5.2 cm PV solar cells. Since the current generated by a PV cell is directly proportional to the active area of a PV solar cell, it should be appreciated that the smaller size a PV solar cell is, offer the larger reduction of electrical current is and accordingly, the larger reduction in power losses is.

Reference is also made to FIG. 2, schematically showing an example prior art solar-array module 32, including crisscross configuration of solar sub-cells 27. In this, example, solar-array module 32 includes 48 (as shown, with no limitations) solar sub-cells 27, arranged in 8 columns (“strings 26” c₁-c₈), as in solar-array module 30, and 6 rows (r₁₁-r₂₃), wherein each column includes 6 solar sub-cells 27, connected by parallel interconnections, forming a crisscross configuration. However, solar sub-cells 27 are substantially smaller than common solar cells 25. In this non-limiting example, solar sub-cells 27 are sized about 15.6 cm>5.2 cm compared with common sized solar cells 25, being about 15.6 cm×15.6 cm. Hence, by forming a sub string 28 of 3 solar sub-cells 27, that combined have the same light exposable area, the voltage sub string 28 is multiplied by 3, while the electrical current is divided by 3. In the example shown in FIG. 2 the 48 solar sub-cells 27 are equivalent to two rows of solar cells 25 in power produced. Therefore, 144 solar sub-cells 27, arranged in m (8 in this example) columns and 3n (18 in this example) rows, are required to produce the same power produced by solar-array module 30.

Since the electrical current in solar-array modules composed of solar sub-cells only is substantially lower than in solar-array modules having one or more common solar cells. The serial connection of common solar (PV) cells or sub-cells may be done using foil-based wiring technology, for example with no limitations, the foil based on the “SmartWire Connection Technology” (“SWCT”,“SWCT technology”) by MEYER BURGER AG [CH], and also described in European Patent Application 3165361 and in “SmartWire Connection Technology” by T. Soderstroma et. al, as shown in FIG. 3a and depicted in FIG. 3b. In such technology, referred to hereinafter as “polymer-based-conductor” technology or simply “polymer conductor” technology, each common solar cell 25 is laminated with a foil 50, on one or both sides, wherein the foil 50 includes between 15 and 38 thin wires 52, each carrying substantially reduced electrical current. The thinner wires 52 are also more ductile than the common cells wiring and reduce the cost of the overall wiring, with respect to the wiring used with common PV cells in common solar modules.

The wires are round Cu-based wires coated with a low melting-point alloy, generally an alloy layer of 3-5 μm in thickness with 50% Indium. The wires 52 are embedded in the polymer foil 50 that is applied directly onto the metallized cell, and the stack is then laminated together. The wires 52 are bonded to the metallization of the cell and provide electrical contact to the metals (e.g. Cu, Ag, Al, Ni, and their alloys). The number of wires 52 and their thickness can be customized to match almost any cell metallization design or cell power class. It should be noted that by bonding multiple wires 52, ohmic losses and/or finger thickness can be limited, as the number of wires can be adapted to the specific cell design. It should be further noted that commonly used busbars on the cell surface (both on the front and back side) are not needed. It should be further noted that the bonding is typically done by heating the polymer-based-conductor to 125° C. (or any other predesigned temperature), to thereby weld the wires to the metallized body of the solar cell.

### SUMMARY

The principle intentions of the present disclosure include providing methods of assembling solar modules including forming crisscross configurations using the polymer conductor technology or regular single conductor wiring technology or a combination thereof.

It should be appreciated that since in the polymer conductor technology provides thinned conductive wires, a polymer conductor foil segment is more ductile than the common cells wiring.

It should be further appreciated that the polymer conductor technology used for connecting series of regular solar cells (25) or sub-cells (27) facilitates bringing adjacent solar sub-cells closer together to minimize the gap formed between some or each one of the cells. The neighboring solar cells or solar sub-cells connection in parallel into a crisscross matrix array may be done using polymer-based-conductors with short transverse wiring that consists a number of thin wires or using short regular transverse wires (conductors) that optionally may embedded in a short segment of a polymer-based-conductor.

It should be noted that throughout the present disclosure, the invention is described using the text and related drawings. The equations are included only as a possible help to persons skilled in the art, and should not be considered as limiting the invention in any way. Various other equations may be used by persons skilled in the art.

According to the teachings of the present inventions there is provided a solar power generation module for maximizing the power generated from the solar module and for minimizing the power degradation inflicted by light obstructions, the module includes a plurality of common solar cells or solar sub-cells, herein after referred to as “solar cells”,” the solar cells are arranged in a physical matrix of N columns and M rows.

At least one pair of neighboring rows of solar cells is mechanically and electrically interconnected by a single wide polymer conductor stripe, being a ductile conductive wiring connection technology, that extends over at least two adjacent columns of the at least one pair of neighboring rows.

At least one pair of neighboring solar cells in each column of solar cells is electrically interconnected in series by at least one respective thin wire conductors embedded inside the polymer conductor stripe.

All solar cells in each pair of neighboring rows of a mutual string, are electrically interconnected in series by at least one respective thin wire conductor embedded inside the polymer conductor stripe.

At least one solar cell in each string of solar cells is electrically interconnected in parallel to one or two solar cells, situated in a mutual row of an adjacent string, by a parallelly-connection conductive means.

In one embodiment, the parallelly-connection conductive means is at least one elongated common conductive wire disposed between the rows of the solar cells, across all strings, or onto the solar cells, across all strings, and wherein said elongated common conductive wire is conductively attached to the wire conductors to locally form at least a partial conductive grid.

In another embodiment, the parallelly-connection conductive means is at least one thin wire conductor embedded inside a single or conductively chained lateral polymer conductor cross stripe that is disposed between the rows of the solar cells across all strings, and wherein said lateral polymer conductor cross stripe is conductively attached to the wire conductors to locally form at least a partial conductive grid.

In yet another embodiment, the parallelly-connection conductive means is at least one thin wire conductor embedded inside a stripe of a single (or conductively chained) lateral polymer conductor cross stripe that is disposed onto the solar cells of the at least one row of solar cells, and wherein said lateral polymer conductor cross stripe is conductively attached to the wire conductors to locally form at least a partial conductive grid.

In yet another embodiment, the parallelly-connection conductive means include a plurality of short conductors, wherein each of the short conductors mechanically interconnects adjacent solar cells of adjacent strings of solar cells, and wherein the short conductor electrically interconnected in parallel the adjacent solar cells.

In one embodiment, the short conductors are short common conductive wires or wide conductor segments.

In another embodiment, the short conductors are short lateral polymer conductor cross segments having at least one thin wire conductor embedded there inside. Optionally, when the solar cells are common solar cells, the parallelly-connection conductive means include the plurality short conductors, wherein each of the short conductors mechanically interconnects adjacent solar cells of adjacent string of solar cells, and wherein the short lateral polymer conductor cross segments electrically interconnect in parallel the adjacent solar cells. Optionally, when the solar cells are common solar cells are solar sub-cells, each pair of solar cells in each column, is electrically interconnected in series by the thin wire conductors embedded inside a narrow polymer conductor stripe, instead of the single wide polymer conductor stripe. In yet another option, each pair of solar cells in each column, is electrically interconnected in series of by the thin wire conductors embedded inside a wide polymer conductor stripe.

Optionally, when the solar cells are solar sub-cells, each pair of solar sub-cells in each column, is electrically interconnected in series of by the thin wire conductors embedded inside a narrow polymer conductor stripe, instead of the single wide polymer conductor stripe.

Optionally, the minimum gap formed in string of solar cells between adjacent common solar cells is ga, being limited by the thickness and ductility of the wire conductors embedded inside a common polymer conductor stripe used in common solar modules polymer stripe wiring, wherein when the solar cells are solar sub-cells, the minimum gap gb formed in a string of solar sub-cells between adjacent solar sub-cells, the solar sub-cells being mechanically and electrically interconnected in series by the polymer conductor stripe, the polymer conductor stripe segment including thinner embedded wires and since the stripe segment is more ductile than a common polymer conductor stripe segment, that facilitates narrowing gap gb, such that ga>gb.

The gap gc formed between each of the adjacent solar cells of adjacent strings of solar cells can be minimized, said adjacent solar cells being electrically interconnected in parallel. the gap gc is mechanically and electrically bridged by the short conductors, wherein the short conductors are selected from a group of conductors including:

a short polymer conductor segment having at least one thin wire conductor embedded there inside;

a single polymer conductor stripe (156, 150) having at least one wide conductor segment (600, 602, 604) embedded there inside;

a polymer conductor segment (610) including:
a) a polymer conductor portion (612) configured to mechanically and electrically interconnect in series one pair of solar cells of adjacent pair of rows of solar cells; and
b) a wide conductor wing portion (614) extending from one predesigned side of the polymer conductor segment (610), being the short conductor,

wherein the wide conductor wing portion (614) is configured to be conductively attached to the polymer conductor portion (612) of next adjacent polymer conductor segment (610) of the next pair of solar cells of the adjacent pair of rows;

a polymer conductor segment (611) including:
a) a polymer conductor portion (613) configured to mechanically and electrically interconnect in series one pair of solar cells of adjacent pair of rows of solar cells;
b) a wide conductor wing portion (614b) extending from one predesigned side of the polymer conductor portion (613), the wide conductor wing portion (614b) being the short conductor; and
c) a second receiving conducting wing (615) extending from the second side of the polymer conductor portion (612),

wherein the wide conductor wing portion (614b) is configured to be conductively attached to the second receiving conducting wing (615) of next adjacent polymer conductor segment (611) of the next pair of solar cells of the adjacent pair of rows; and

a single wide polymer conductor stripe (620) that extends over at least two adjacent columns of the at least one pair of adjacent rows, including the gap gc formed there between the at least two adjacent columns, the single wide polymer conductor stripe (620) including:
a) a polymer conductor segment (150) configured to mechanically and electrically interconnect in series each pair of solar cells of the adjacent pair of rows; and
b) a wide conductor wing portion (624),

wherein the wide conductor wing portion (624) is configured to bridge over the gc and thereby electrically connect the respective pair of solar cells, of the at least two adjacent columns, in parallel.

Optionally, the conductive attachment of the wide conductor wing portion (614a, 614b) to the polymer conductor portion (612) of next adjacent polymer conductor segment (610) of the next pair of solar cells of the adjacent pair of rows is performed by a welding step.

Optionally, the conductive attachment of the wide conductor wing portion (614a, 614b) to the second receiving conducting wing (615) of next adjacent polymer conductor segment (611) of the next pair of solar cells of the adjacent pair of rows is performed by a welding step.

The welding step may include heating to a melting temperature.

The conductivity of the wide conductors (600, 602, 604, 614a, 614b) is attained by conductive metal or by adhesive conductive glue.

A solar array module may have a common surface area preconfigured to accommodate a matrix of common solar cells interspaced by the gaps ga and gs, the solar array module, being reconfigured to accommodate a matrix of solar sub-cells (27), the solar array module further including a plurality of solar sub-cells (27) electrically interconnected in a crisscross matrix as in any one of claims 5 to 13, wherein at least the majority of the plurality of solar sub-cells (27) are interspaced, respectively, by the gaps gb and gc.

Optionally, all the solar sub-cells have rectangular shape and essentially of equal dimensions.

Optionally, the solar sub-cells were cut from generally square common solar cells fabricated with 4 truncated corners, wherein the cut sub-cells include two edge sub-cell, each having two truncated corners, and optionally, at least one rectangular, inner sub-cell. The cut solar sub-cells may be sorted into groups of solar sub-cells, each group having essentially equal dimensions.

The accommodated matrix of solar sub-cells may have solar sub-cells of essentially equal dimensions or solar sub-cells having mixed dimensions.

### BRIEF DESCRIPTION OF THE DRAWINGS

The present invention will become fully understood from the detailed description given herein below and the accompanying drawings, which are given by way of illustration and example only, and thus not limiting in any way, wherein:

FIG. 1 (prior art) is a schematic illustration showing an example solar-array module, having a crisscross configuration of solar cells.

FIG. 2 (prior art) is a schematic illustration showing an example solar-array module, having a crisscross configuration of solar sub-cells.

FIG. 3a (prior art) is a cross-section illustration of an example PV solar cell having a face that is laminated with a foil that includes multiple thin conductive wires.

FIG. 3b (prior art) depicts an example of a PV solar cell having a face that is being laminated with a polymer conductor foil that includes between multiple thin conductive wires, as shown in FIG. 3a.

FIG. 4a (prior art) is a schematic illustration of an example solar array of solar cells arranged in pairs of rows, wherein in one pair of two neighboring rows example singular pairs of cells are shown mechanically and electrically interconnected in series by a respective polymer conductor segment, wherein in some other rows, pairs of cells of are mechanically interconnected by a single stripe of a polymer conductor segment, and wherein conductive wires embedded within the single polymer conductor stripe electrically interconnects in series each pair of cells of the adjacent rows.

FIG. 4b (prior art) is a schematic cross section (BB') illustration showing a pair of solar cells, interconnected by a polymer conductor technology.

FIG. 5 which illustrates pairs of rows, shown for clarification purposes only, according to the teachings of the present disclosure, wherein all pairs cells in each pair of rows are mechanically and electrically interconnected by a single wide polymer conductor stripe, extending over all of the solar cells across all columns.

FIG. 6a is a schematic illustration of an example solar module of solar cells arranged in an array, wherein pairs of solar cells of pair of two neighboring rows are mechanically interconnected by a single stripe of a polymer conductor segment, and wherein conductive wires embedded within the single wide stripe electrically interconnects in series each of the pairs of solar cells of each of the two neighboring rows.

FIG. 6b is a schematic cross section (DD′) illustration showing a string of solar cells, interconnected by a respective polymer conductor segment.

FIG. 7a is a schematic illustration of an example solar array module, including a crisscross configuration of solar cells, in a 6×8 solar cells matrix, wherein each two neighboring rows of cells are serially mechanically interconnected by a single wide stripe of a polymer conductor, wherein each pair of neighboring cell in respective rows of the two neighboring rows are electrically interconnected in series by that polymer conductor stripe segment, and wherein all serially formed strings are parallelly interconnected by a single common wire.

FIG. 7b is a schematic cross section (GG') illustration showing a string of serially connected solar cells, wherein each cell of the string is serially connected to a neighboring cell by a single short stripe of a polymer conductor segment that incorporates all cells of two neighboring rows, and wherein all strings are parallelly interconnected by a common wire, as shown between each pair of neighboring cells.

FIG. 8a is a schematic illustration of an example solar array module, including a crisscross configuration of solar cells, in a 6×8 solar cells matrix, wherein each pair of neighboring cells of each two neighboring rows of cells are electrically interconnected in series by the wires of each folded single stripe of polymer conductor, that extends over the two neighboring rows, across all columns, and wherein all strings are electrically interconnected in parallel by the thin wires embedded in each respective elongated polymer conductor stripe of polymer conductor or by at least two conductive wires that are thinner than a common conductive wire that extends between the two neighboring rows, across all columns.

FIG. 8b is a schematic cross section (HH') illustration showing, wherein each cell of the string is serially connected to a neighboring cell by a folded single stripe of polymer conductor that extends over the two neighboring rows, across all columns, wherein all strings are electrically interconnected in parallel by the thin wires embedded in an elongated stripe of polymer conductor that is disposed above and electrically interconnected to each of the folded single segments of polymer conductor.

FIG. 8c is a schematic cross section illustration showing a string of serially connected solar cells, wherein each cell of the string is serially connected to a neighboring cell by a folded single segment of polymer conductor, wherein respective polymer conductor parallel connection segments, having a number of thin wires embedded there inside, are shown between each pair of cells neighboring of neighboring rows, being disposed below, and electrically interconnected to the folded single segment of polymer conductor.

FIG. 9 is a schematic illustration of an example solar array module, arranged in a crisscross configuration of solar cells in a 6×8 solar cells matrix, wherein each two neighboring rows of cells are electrically interconnected in series by a wide single folded stripe of polymer conductor segment, in which stripe the wires extend along the strings of cells that are electrically connected in series, and wherein each row of cells in all strings is electrically interconnected in parallel by a single stripe of elongated polymer conductor segment that is disposed onto solar cells and in which stripe the embedded thin wire conductors extend over the two neighboring rows, across all columns.

FIG. 10a schematically illustrates another example solar array module that includes a crisscross configuration of solar cells, in a 6×8 solar cells matrix, featuring examples singular pairs of solar cells that are electrically connected in series by a respective polymer conductor stripe segment having a plurality of conductive thin wires embedded there inside, wherein each row of cells is electrically interconnected in parallel by another single lateral polymer conductor stripe that is disposed onto the solar cells and in which stripe the thin wire conductors extends over the two neighboring rows, across all columns, and wherein the thin wire conductors of both polymers are electrically interconnected (forming a grid wire conductors that conductively intersect therebetween).

FIG. 10b schematically illustrates another example solar array module that includes a crisscross configuration of solar cells, in a 6×8 solar cells matrix, featuring examples singular pairs of solar cells that are electrically connected in series by a respective polymer conductor stripe segment having a plurality of conductive thin wires embedded there inside, wherein the solar cells of each row of cells is electrically interconnected in parallel by another single lateral polymer conductor stripe in which stripe the thin wire conductors extends between the two neighboring rows, across all columns, and wherein the thin wire conductors of both polymers are electrically interconnected (forming a grid wire-conductors that conductively intersect therebetween).

FIG. 11 schematically illustrates another example solar array module that includes a crisscross configuration of solar cells, in a 6×8 solar cells matrix, featuring examples singular pairs of solar cells that are electrically connected in series by a respective polymer conductor stripe segment having a plurality of conductive thin wires embedded there inside, wherein short polymer conductor segments electrically connect (some or each one of) to the respective neighboring cells, to facilitate the required parallel electric connections.

FIG. 12 schematically illustrates another example solar array module that includes a crisscross configuration of solar cells or sub-cells, in a 6×8 solar cells matrix, featuring example singular pairs of solar cells that are electrically interconnected in series by a single wide stripe of polymer conductor that mechanically interconnecting singular pairs of neighboring cells in all columns of cells, in which stripe the conductive wires electrically connect the each pair of cells or sub-cells in series, wherein respective short polymer conductor segments electrically connect between (some or each one of) neighboring cells in each row in parallel.

FIG. 13 schematically illustrates another example solar array module with no limitation that includes a crisscross configuration of solar cells or sub-cells, in a 6×24 solar cells or sub-cells matrix, featuring examples of plurality of single pairs of cells or solar sub-cells in neighboring rows that are electrically connected in series by polymer conductor segments having at least one conductive thin wire embedded there inside, wherein respective short polymer conductor segments electrically connect between (some or each one of) neighboring cells in each row in parallel.

FIG. 14a schematically illustrates another example portion of a solar array matrix, showing a pair of strings (or a portion thereof) of solar cells, wherein each string of solar cells is composed of pairs of solar cells electrically interconnected in by segments of polymer conductor, and wherein some or each solar cells is also electrically interconnected in parallel with its neighboring solar cells by an individual short polymer conductor segment.

FIGS. 14b and 14c are schematic cross section (LL′ and MM′, respectively) illustration showing pairs of solar cells interconnected serially in string of solar cells, wherein some or each solar cell in row of solar cells is parallelly interconnected by a short stripe of polymer conductor segment to the respective neighboring solar cells in the neighboring rows.

FIG. 15a illustrates two pairs of solar cells, wherein each pair of solar cells includes cells from a pair of adjacent rows of cells, as shown in FIG. 4a, wherein the example singular pairs of cells are mechanically and electrically interconnected in series by respective polymer conductor segments and wherein the gap formed between the two pairs of cells is gs.

FIG. 15b illustrates two pairs of solar cells, wherein each pair of solar cells includes cells from a pair of adjacent rows of sub-cells, as shown in FIG. 4a in rows r1 and r2, and wherein the example singular pairs of sub-cells are mechanically and electrically interconnected in series by respective polymer conductors segment and wherein the gap formed between the two cells is minimized to gc.

FIG. 15c illustrates two pair of solar cells, wherein each pair of solar cells includes cells from a pair of adjacent rows, wherein the two pairs of cells are mechanically interconnected by a single wide stripe of a polymer conductor, and wherein conductive thin wires embedded within that single polymer conductor stripe electrically interconnects in series each of the two pairs of cells and wherein the gap formed between the two cells is minimized to gc.

FIG. 15d illustrates the two solar cells shown in FIG. 15c, wherein the wide polymer conductor foil segment further includes a wide segment conductor having a width wc, where wc>gc.

FIGS. 15e and 15f illustrate optional segmentations of the wide polymer conductor shown in FIG. 15d, into example parallel interconnections between pair of solar cells.

FIG. 16a illustrates two rows of pairs of solar cells, as shown in FIGS. 15d-15f, wherein the polymer conductor segment further includes wide wing conductor, according to some aspects of the present disclosure.

FIG. 16b illustrate the pair of rows of solar cells, as shown in either FIGS. 16a or (approximately) 16c, after the welding step, wherein the solar cells in each of the rows are electrically connected in parallel by the formed welded wide stripe conductor.

FIG. 16c is a variation of the arrangement shown in FIG. 16a, wherein a polymer conductor segment used is narrower than polymer conductor segment used in the arrangement shown in FIG. 16a, according to some aspects of the present disclosure.

FIG. 17 illustrate the pair of rows of solar cells according to some other aspects of the present disclosure, wherein the pair of neighboring rows of singular pairs of solar cells are interconnected by a single wide stripe of polymer conductor segment that mechanically and electrically interconnecting the singular pairs of neighboring cells across all columns of solar cells, wherein the wide stripe of polymer conductor segment further includes a number of wide wires such that when placed over the singular pairs of to neighboring cells across all columns of solar cells, and wherein the wide wires facilitate a parallel electrical connection between the solar cells of the pair of rows.

FIG. 18a illustrates a common size PV solar cell having a generally square shape with four truncated corners and sized approximately 15.6 cm×15.6 cm.

FIGS. 18b and 18c illustrate a non-limiting example, showing a common size PV solar cell subdivided into 2 edge sub-cells having a first size (j), and 3 inner rectangular sub-cells having a second size (k).

FIG. 19 illustrates a non-limiting example solar module having a matrix layout of 60 inner, rectangular sub-cells arranged in a crisscross configuration.

FIG. 20 illustrates a non-limiting example solar module having a matrix layout of 60 edge sub-cells arranged in a crisscross configuration.

FIG. 21 illustrates a non-limiting example is shown in, combing 24 edge sub-cells and 36 rectangular sub-cells into a module having 60 solar sub-cells arranged in a crisscross configuration.

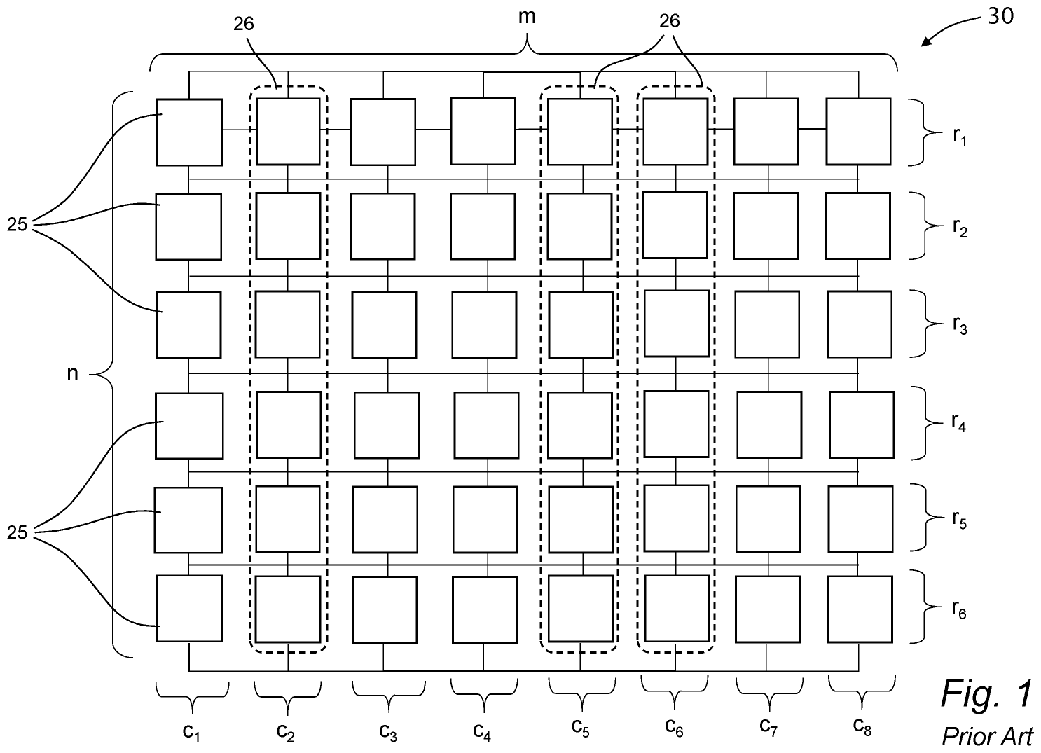

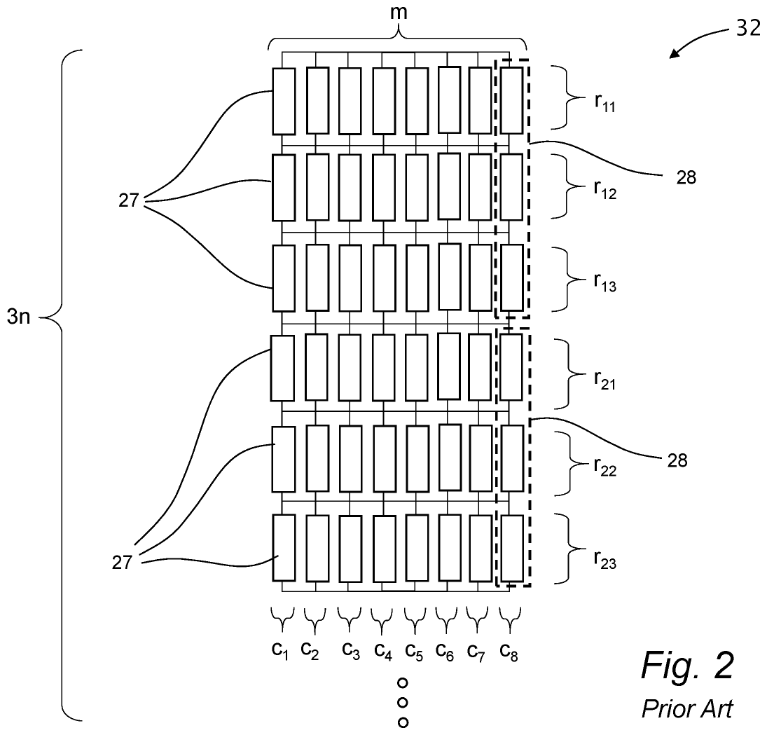

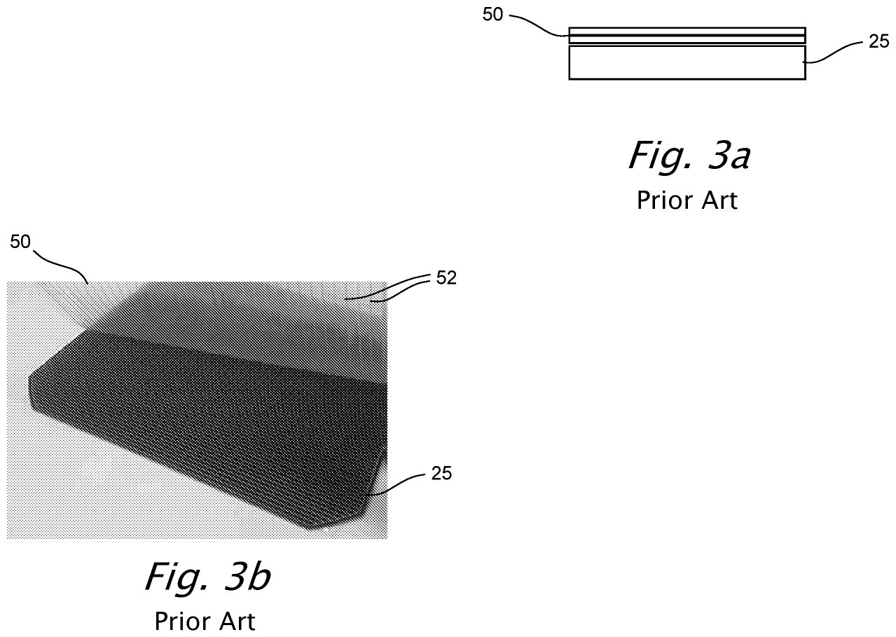

### DETAILED DESCRIPTION

The invention now will be described more fully hereinafter with reference to the accompanying drawings. This invention may, however, be embodied in many different forms and should not be construed as limited to the embodiments set forth herein; rather, these embodiments are provided, so that this disclosure will be thorough and complete, and will fully convey the scope of the present invention to those skilled in the art.

Unless otherwise defined, all technical and scientific terms used herein have the same meaning as commonly understood by one of ordinary skill in the art to which the present invention belongs. The methods and examples provided herein are illustrative only, and not intended to be limiting.

It should be noted that the description refers hereon to solar cells, referring either to common solar cells or to solar sub-cells.

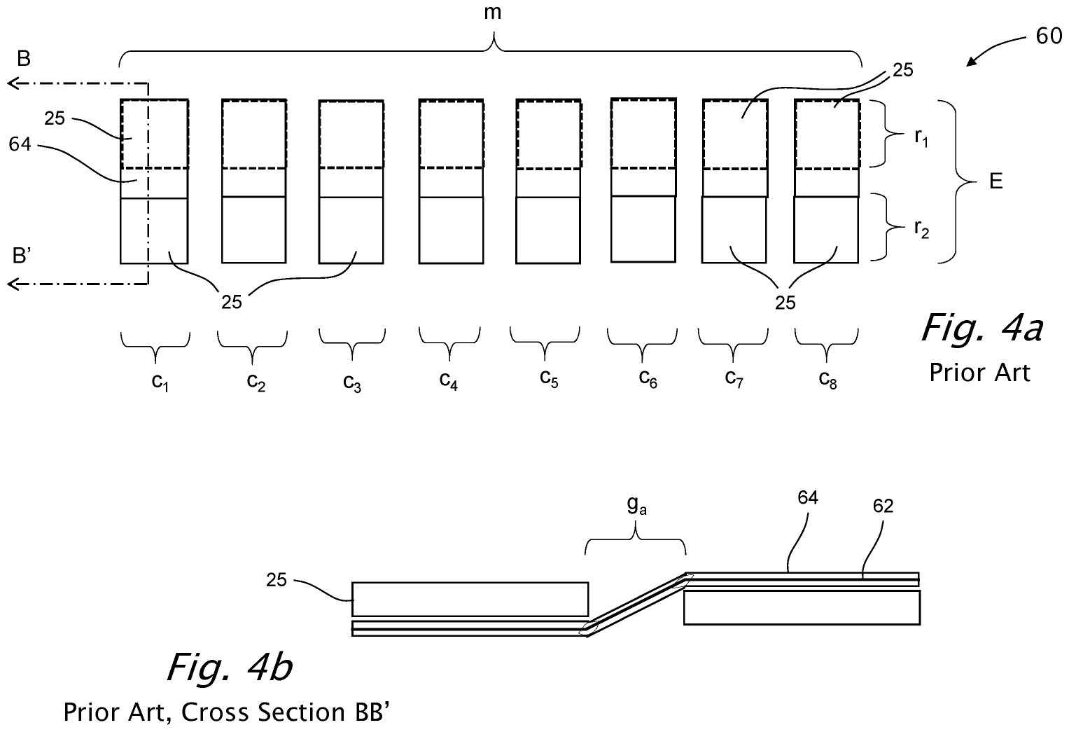

Reference is now made to the drawings. FIG. 4a schematic illustration of an example prior art pair of rows 60 of solar cells (25, 27) with 8 solar cells in each row, featuring example rows having singular pairs (E) of common solar cells 25 (or solar sub-cells 27), that are electrically interconnected in series by a narrow ductile polymer conductor segment 64 having a plurality of thin wire conductors 62 (see FIG. 4b) embedded there inside. Two example rows of solar cells (25, 27), are labeled in this non-limiting example as rows r1-r2 (see FIG. 4a), and the plurality of columns or strings 26 of solar cells (25, 27), are labeled in this non-limiting example as strings of columns c1-c8. FIG. 4b (prior art) is a schematic cross section (BB') illustration showing a pair of solar cells (25, 27), of solar cells (25, 27), interconnected by segments of the polymer conductor segment 64 having thin wire conductors 62. It should be appreciated that the wire conductors 62 being thin, facilitate the ductility of the polymer conductor segment 64, and minimizes the light obstruction of the wires. It should be further appreciated a narrow polymer conductor stripe 64 should extend serially over just one column (string), for each pair of neighboring rows, which defines the width of polymer conductor stripe 64 being narrow.

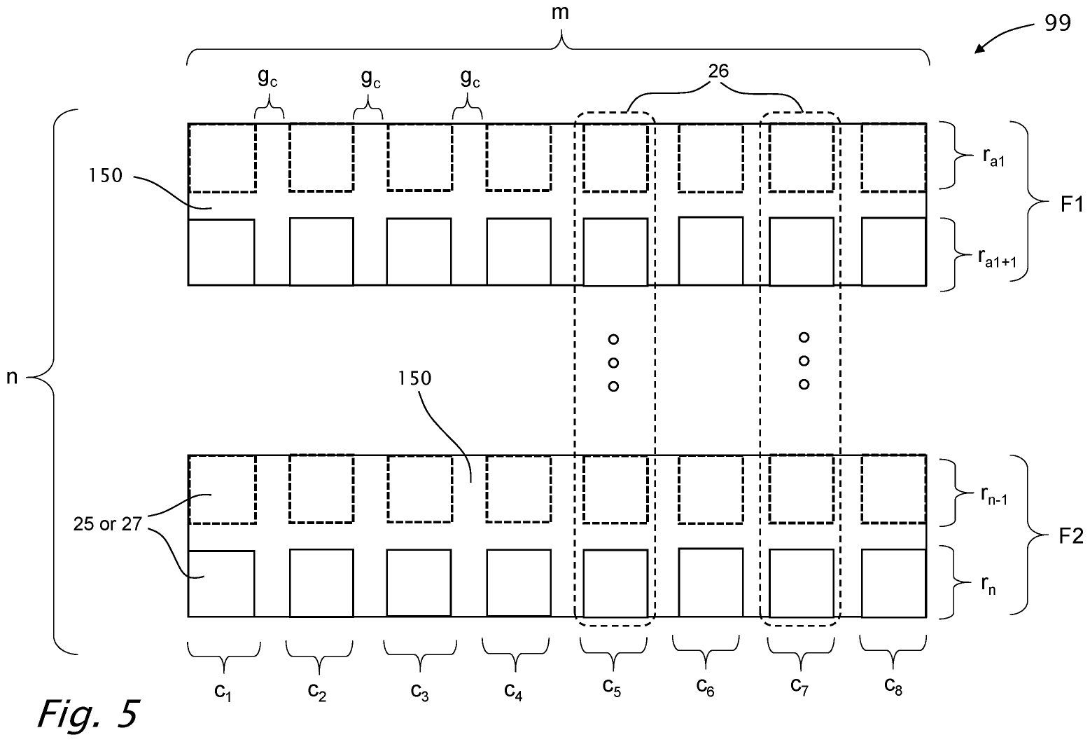

Reference is now made to FIG. 5 which illustrates a pair of rows Fl and F2, shown for clarification purposes only, according to the teachings of the present disclosure. Each of the pairs of rows Fl and pair of rows F2 include pairs of solar cells (25, 27), in each respective column c1-c8, wherein all pairs cells, (25, 27) in each pair of rows F1 and F2, are mechanically and electrically interconnected by a single wide polymer conductor stripe 150, wherein stripe 150 extends over all of the solar cells (25, 27) of the two neighboring rows, across all columns (c1-c8). It should be appreciated a wide polymer conductor stripe 150 should extend over at least two adjacent columns of each pair of neighboring rows, which defines the minimum width of wide polymer conductor stripe 150, compared with narrow polymer conductor stripe 64. The pair of rows Fl and pair of rows F2 include pairs of solar cells (25, 27), in each column c1-c8, wherein each pair of cells (25, 27) is electrically interconnected in series by at least one conductive wire embedded in the single wide polymer conductor stripe 150.

It should be appreciated that when connecting the solar cells (25, 27) of neighboring strings in parallel, the gap formed between the two neighboring solar cells (25, 27) of the pair of strings of solar cells (25, 27), can be minimized to gc.

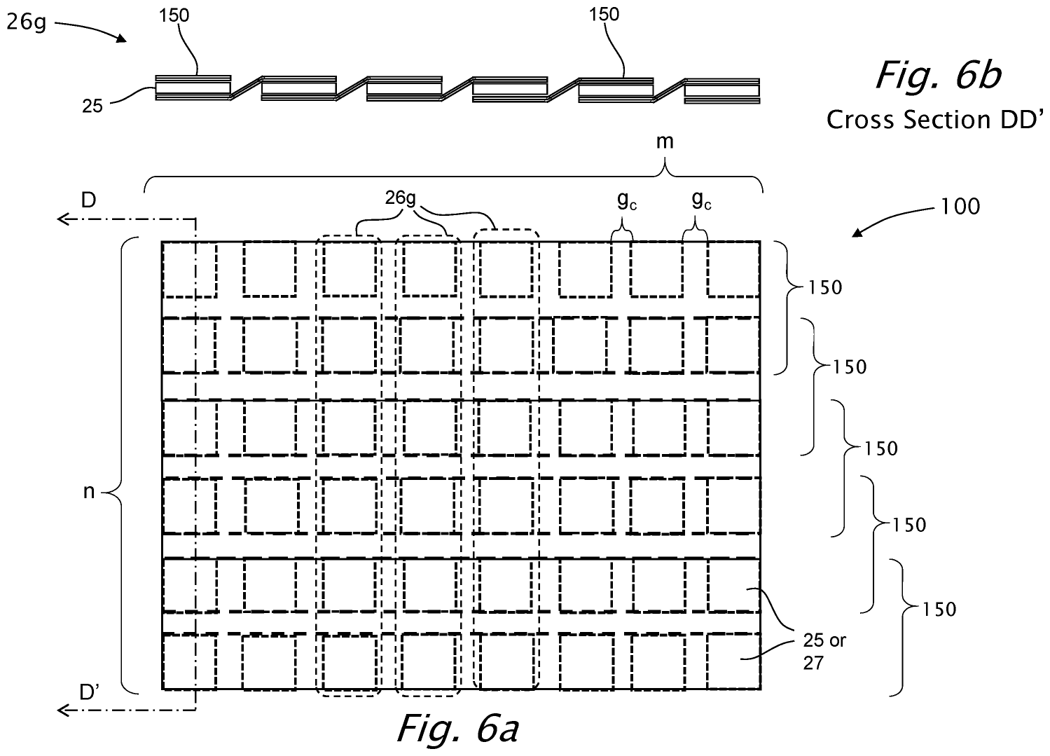

FIG. 6a is a schematic illustration of an example solar module 100 of solar cells arranged in an array having a n×m (6×8 in the shown example) solar cells matrix, wherein the solar cells (25, 27) of each pair of neighboring rows are mechanically and electrically interconnected by a single wide stripe 150 of a ductile polymer conductor that extends over all of the solar cells (25, 27) of the two neighboring rows, and wherein conductive wires embedded within the single wide polymer conductor stripe 150 electrically interconnects in series each of the pairs of solar cells (25, 27) in each column c1-c8 of each of the two neighboring rows, and thereby, all strings 26g are electrically connected in series.

FIG. 6b is a schematic cross section (DD') illustration showing a string 26g of solar cells (25, 27), interconnected by a wide polymer conductor stripe 150. Each individual pair of cells 25 in the m columns shown, is mechanically and electrically interconnected in series by a respective single wide stripe 150 of a polymer conductor stripe, such as a polymer conductor foil segment (provided as a non-limiting example).

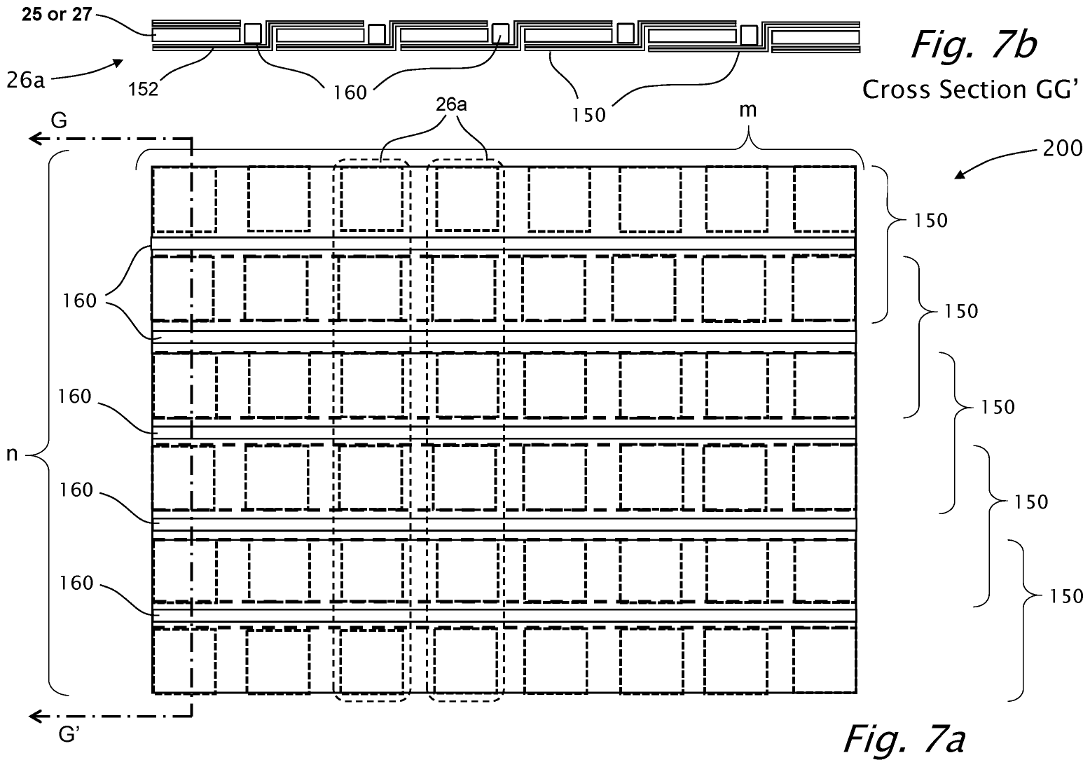

FIG. 7a is a schematic illustration of an example solar array 200 of solar cells (25, 27) arranged in an array suitable for a crisscross configuration, forming a n×m (6×8 in the shown example) solar cells matrix, wherein each two neighboring rows of solar cells (25, 27), are mechanically and electrically interconnected in series by a single wide (extending over at least two adjacent columns of each pair of neighboring rows) polymer conductor stripe 150, and wherein the cells in each strings 26a are electrically interconnected in parallel by an elongated single common conductive wire 160 (typically thicker than 1 mm) disposed between the rows of cells across all strings 26a . FIG. 7b is a schematic cross section (GG′) illustration, showing a string 26a of serially connected solar cells (25, 27), mechanically and electrically, wherein each solar cell of the string 26a is electrically connected in series to a neighboring cell (25, 27) by a wide single folded segment of a polymer conductor stripe 150, and wherein the common wire 160 is shown between each pair of neighboring cells (25, 27), above the respective folded segment of a polymer conductor.

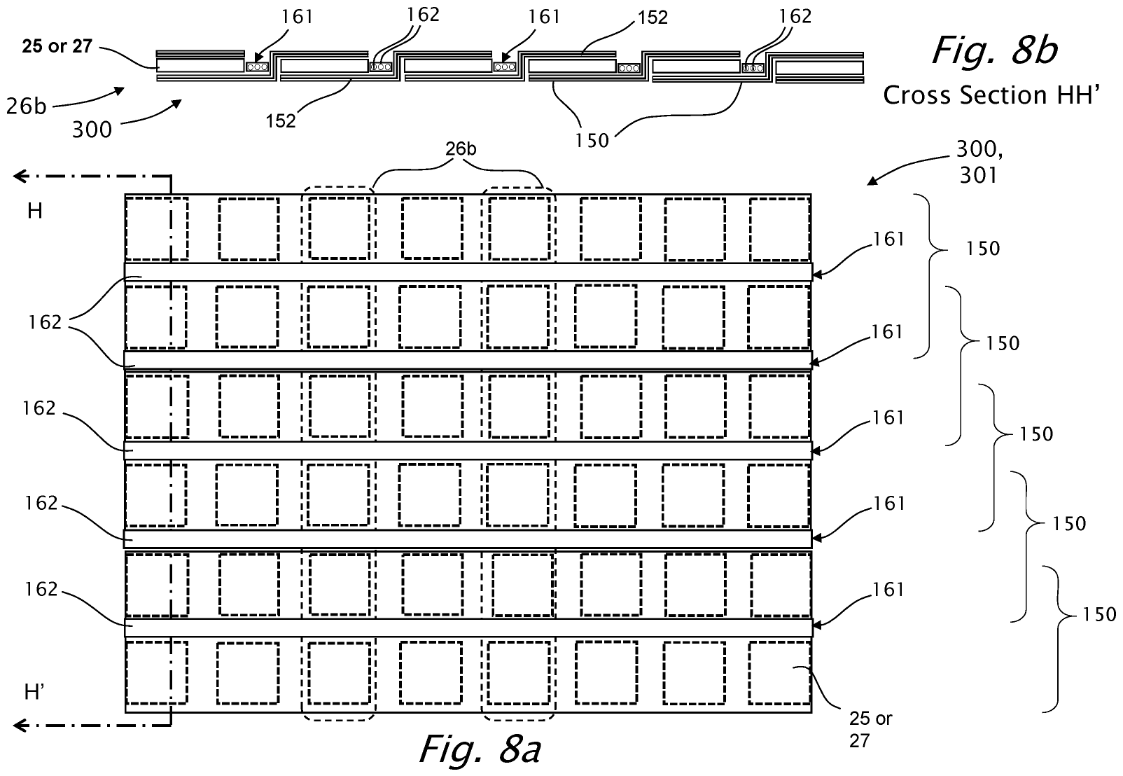

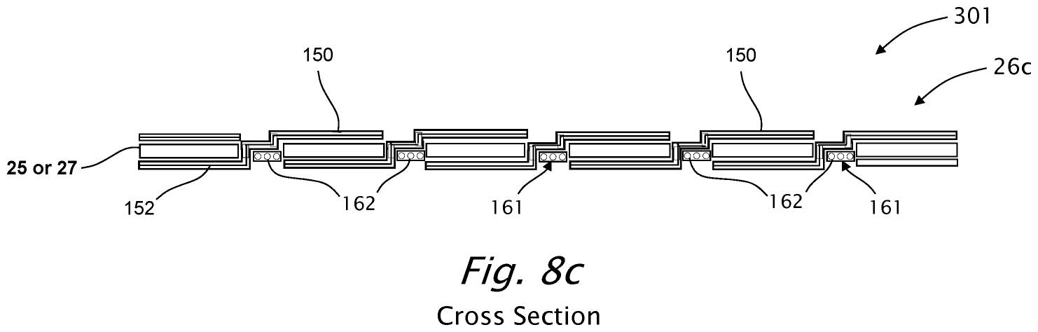

FIG. 8a is a schematic illustration of an example solar array 300 of solar cells (25, 27) arranged in an array suitable for a crisscross configuration, forming a 6×8 solar cells matrix 300, wherein each two neighboring rows of solar cells (25, 27) are mechanically and electrically interconnected in series by a single wide polymer conductor stripe 150, and wherein the cells in each string 26b are electrically interconnected in parallel by a single lateral polymer conductor cross stripe 161 (or alternatively, a number of thin common conductors) disposed between the rows of cells and extending across all strings 26b. Each pair of neighboring cells (25, 27) in each of the rows of the two neighboring rows are electrically interconnected in series by the wire conductors 152 embedded in the respective wide polymer conductor stripe 150 that extends over at least two adjacent columns of each pair of neighboring rows.

FIG. 8b is a schematic cross section (HH′) illustration showing a string 26b of solar cells (25, 27) that are electrically connected in series by the thin wire conductors 152 embedded in the respective folded single polymer conductor stripe 150 that extends over the two neighboring rows, across at least two adjacent columns of each pair of neighboring rows (shown, with no limitations, being extended across all columns), and wherein each row of cells (25, 27) is parallelly interconnected by another single lateral polymer conductor cross stripe 161, in which lateral cross stripe 161 the wire conductors 162 extend across all strings 26b of cells (25, 27), and wherein the lateral stripe 161 is shown positioned above and electrically interconnected to each of the folded single wide polymer conductor stripes 150. It should be appreciated that the wire conductors 162 embedded in lateral stripe 161 are conductively attached to the wire conductors 152 embedded in the polymer conductor stripe 150, overlapped by lateral stripe 161, to locally form at least a partial conductive grid.

FIG. 8c is a schematic cross section illustration showing pairs of solar cells (25, 27) that are electrically connected in series to form a string 26c, wherein each cell of the string 26c is serially connected to a neighboring cell of a neighboring row, by the thin wire conductors 152 embedded in the respective folded single wide polymer conductor stripe 150, wherein respective polymer conductor parallel electric connection segments 161, having a number of thin wires conductors 162 embedded there inside, are shown between each pair of neighboring cells (25, 27) in each row, and wherein the polymer conductor parallel connection segments 161 are disposed below, and electrically interconnected to each of the respective folded single polymer conductor stripe 150.

FIG. 9 is a schematic illustration of an example solar array 400 of solar cells (25, 27), arranged in an array suitable for a crisscross configuration, forming a 6×8 solar cells matrix 400, wherein each two neighboring rows of solar cells (25, 27), are serially interconnected by a single wide polymer conductor stripe 150, in which wide stripe 150 the wires extend along the strings 26d of solar cells (25, 27) that are electrically connected in series. All solar cells (25, 27) of each row (r1 to r6, some or each one of them) are electrically interconnected in parallel by the thin wire conductors 154 embedded there inside each single (or conductively chained) lateral polymer conductor stripe 155 are disposed onto the cells of the rows of cells and extending across to all strings 26h. It should be appreciated that the wire conductors 154 embedded in lateral stripe 155 are electrically and conductively attached to the wire conductors 152 embedded in the polymer conductor stripe 150, overlapped by lateral stripe 155, to locally form at least a partial conductive grid.

It should be appreciated the when an array of sub-sells 27 only, the electric current in at module is substantially reduced compared with array of common solar cells 25. This facilitate reduction of the thickness of conductive wires, including the wires 72 embedded inside polymer conductor foils 74, compared to polymer conductor foils 64 commonly used in the industry. This may also improve the ductility of the polymer conductor foils 74 as a whole and facilitates reduction of gaps required between cells in strings of cells.

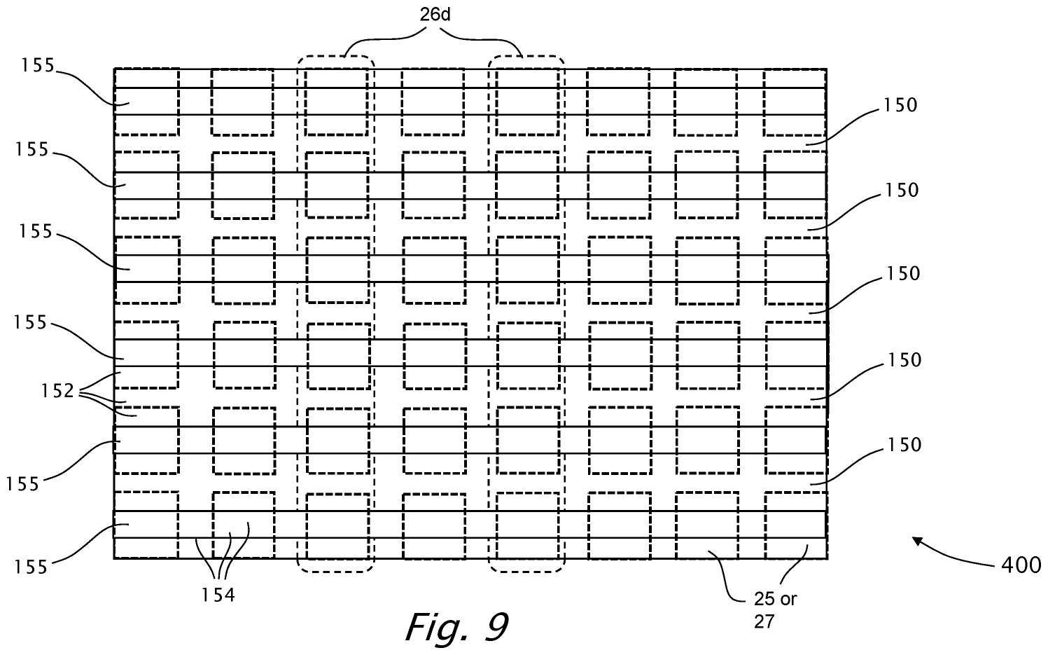

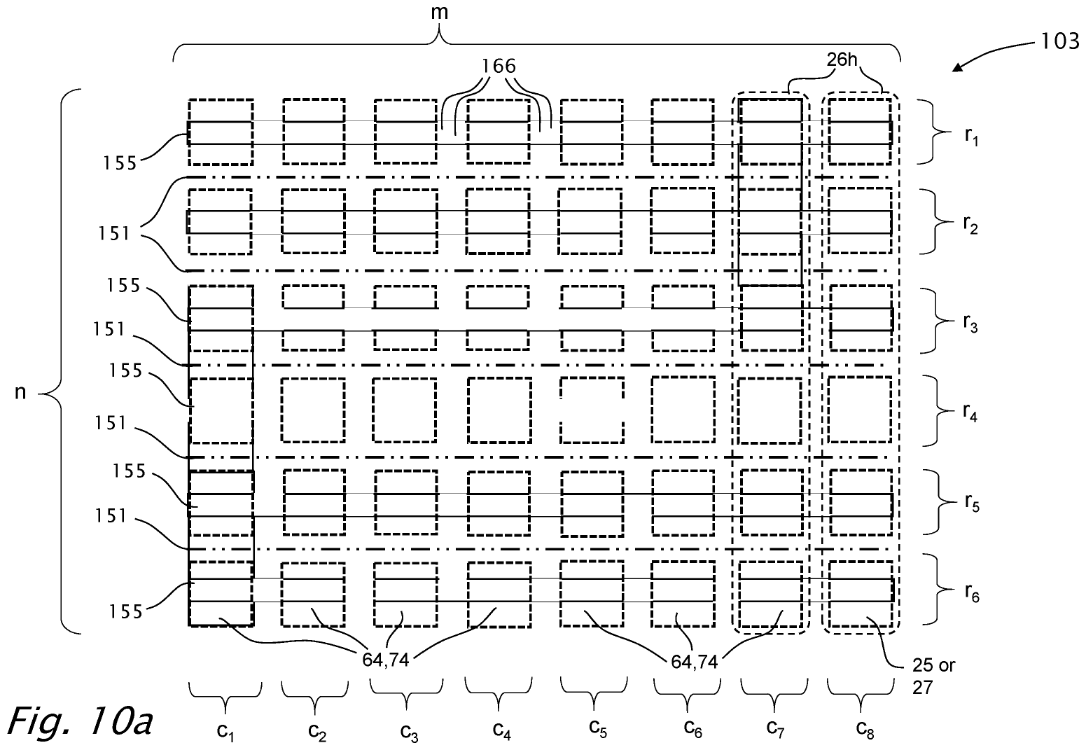

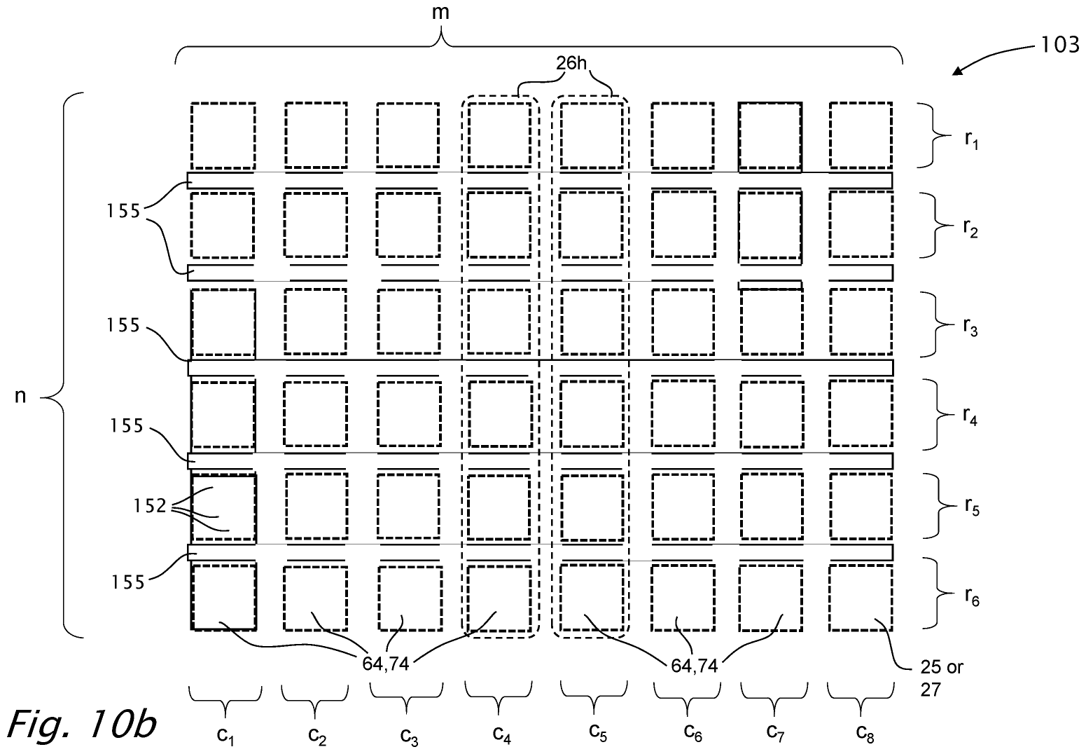

Reference is now made to FIG. 10a, which schematically illustrates another example of a solar array module 103, that includes a crisscross configuration of solar cells (25, 27), in a 6×8 solar cells matrix. Solar array module 103 includes columns (c1-c8 in this example), wherein in each column, pairs of neighboring solar cells (25, 27) are mechanically and electrically interconnected in series by a respective polymer conductor segment (64, 74) having at least one thin wire conductor (62, 72) embedded there inside (typically, a plurality of smart wire conductors (62, 72), forming a string 26h of solar cells (25, 27).

The cells in rows (r1, r2, r3, r4 r5 and r6, some or each one of them) of solar cells (25, 27) are electrically interconnected in parallel by the thin wire conductors 154 embedded there inside each single (or conductively chained) lateral polymer conductor stripe 155, wherein the lateral polymer conductor stripe 155 are disposed onto the cells of the rows of cells and extending across all strings 26h. It should be appreciated that the wire conductors 154 embedded in lateral stripe 155 are electrically and conductively attached to the wire conductors 152 embedded in the polymer conductor stripe 150, overlapped by lateral stripe 155, to locally form at least a partial conductive grid.

Reference is now made to FIG. 10b, which schematically illustrates another example of a solar array module 103, that includes a crisscross configuration of solar cells (25, 27), in a 6×8 solar cells matrix. Solar array module 103 includes columns (c1-c8 in this example), wherein in each column, pairs of neighboring solar cells (25, 27) are mechanically and electrically interconnected in series by a respective polymer conductor segment (64,74) having at least one thin wire conductor 62 embedded there inside (typically, a plurality of smart wire conductors (62,72), forming a string 26h of solar cells (25, 27). The cells (25, 27) in rows (r1 r2, r3, r4 r5 and r6, some or each one of them) of solar cells (25, 27) are electrically interconnected in parallel by the thin wire conductors 154 embedded there inside each single (or conductively chained) lateral polymer conductor stripe 155, wherein the lateral polymer conductor stripe 155 are disposed between the rows of cells and extending across all strings 26h. It should be appreciated that the wire conductors 154 embedded in lateral stripe 155 are electrically and conductively attached to the wire conductors 152 embedded in the polymer conductor stripe 150, overlapped by lateral stripe 155, to locally form at least a partial conductive grid. It should be further appreciated that to folding lines of the polymer conductor segments (64,74) are denoted in FIG. 10a and elsewhere as 151.

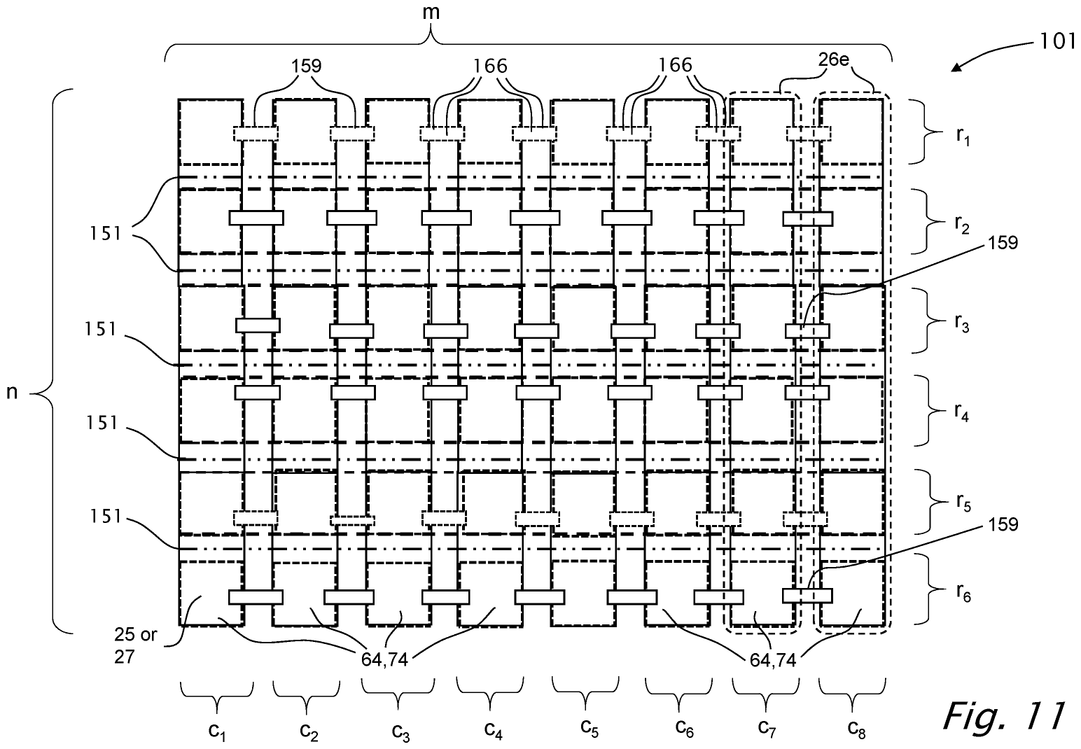

Reference is now made to FIG. 11, which schematically illustrates another example of a solar array module 101, that includes a crisscross configuration of solar cells (25, 27), in a 6×8 solar cells matrix. Solar array module 101 includes columns (c1c8 in this example), wherein in each column, pairs of neighboring solar cells (25, 27) are mechanically and electrically interconnected in series by a respective narrow polymer conductor segment (64, 74) having at least one thin wire conductor (62, 72) embedded there inside (typically, a plurality of smart wire conductors (62, 72), forming a string 26e of solar cells (25, 27). The solar cells (25, 27) in rows (r1, r2, r3, r4 r5 and r6) of solar cells (25, 27) are (some or each one of) electrically interconnected in parallel by wire conductors 166 embedded in respective lateral short polymer conductor segments 159 (or alternatively, by common short common wiring segments). It should be appreciated that the wire conductors 166 embedded in lateral short polymer conductor segments 159 are conductively attached to the wire conductors (62, 72) embedded in the narrow polymer conductor segment (64, 74), overlapped by the respective lateral short polymer conductor segment 159, to locally form at least a partial conductive grid. In the non-limiting example shown in FIG. 11, solar array module 101 is shown in a top view illustration, wherein the short polymer conductor segments 159 in rows r1 to r6 may be conductively connected to the top side, or the bottom side of the respective pair of solar cells (25, 27), or to a respective narrow polymer conductor segment (64, 74) between the cells. It should be appreciated that to folding lines of the narrow polymer conductor segments (64, 74) are denoted in FIG. 11 and elsewhere as 151.

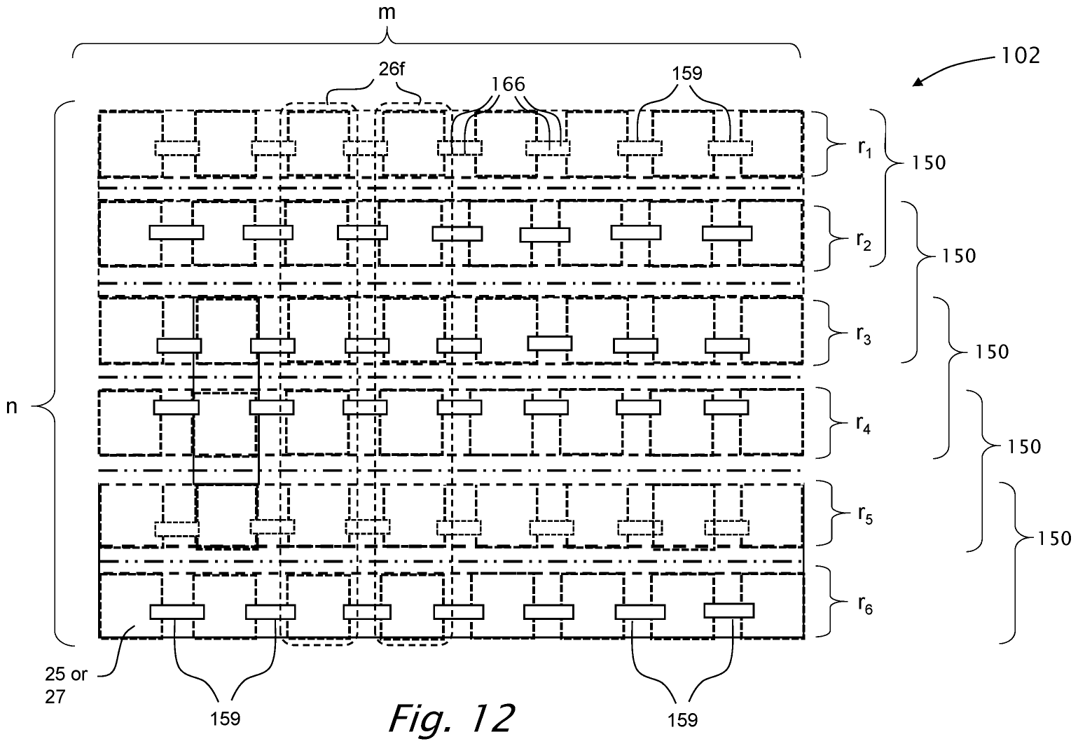

Reference is also made to FIG. 12, which schematically illustrates an example solar array module 102, that includes a crisscross configuration of solar cells (25, 27), in a 6×8 solar cells matrix, wherein each two neighboring rows of solar cells (25, 27) are mechanically and electrically interconnected in series by a wide polymer conductor stripe 150 having a number of thin wire conductors 152 embedded there inside, wherein the wire conductors 152 extend along each pair of neighboring cells (25, 27), to thereby form strings 26f of cells (25, 27). All pairs of solar cells (25, 27) are connected serially by a respective single wide polymer conductor stripe 150 that extends laterally over the two neighboring rows, across all columns. The solar cells (25, 27) of rows (r1, r2, r3, r4 r5 and r6) of solar cells (25, 27) are (some or each one of) electrically interconnected in parallel by wire conductors 166 embedded in respective lateral short polymer conductor segments 159 (or alternatively, by short common wiring segments). It should be appreciated that the wire conductors 166 embedded in lateral short polymer conductor segments 159 are conductively attached to the wire conductors 152 embedded in the polymer conductor stripe 150, overlapped by the respective lateral short polymer conductor segment 159, to locally form at least a partial conductive grid.

In the non-limiting example shown in FIG. 12, solar array module 102 is shown in a top view illustration, wherein the short conductor segments 159 in rows r1 to r6 may be conductively connected to the top side, or the bottom side of the respective pair of (some or each one of) solar cells (25, 27), or to a respective polymer conductor stripe 150 between the cells.

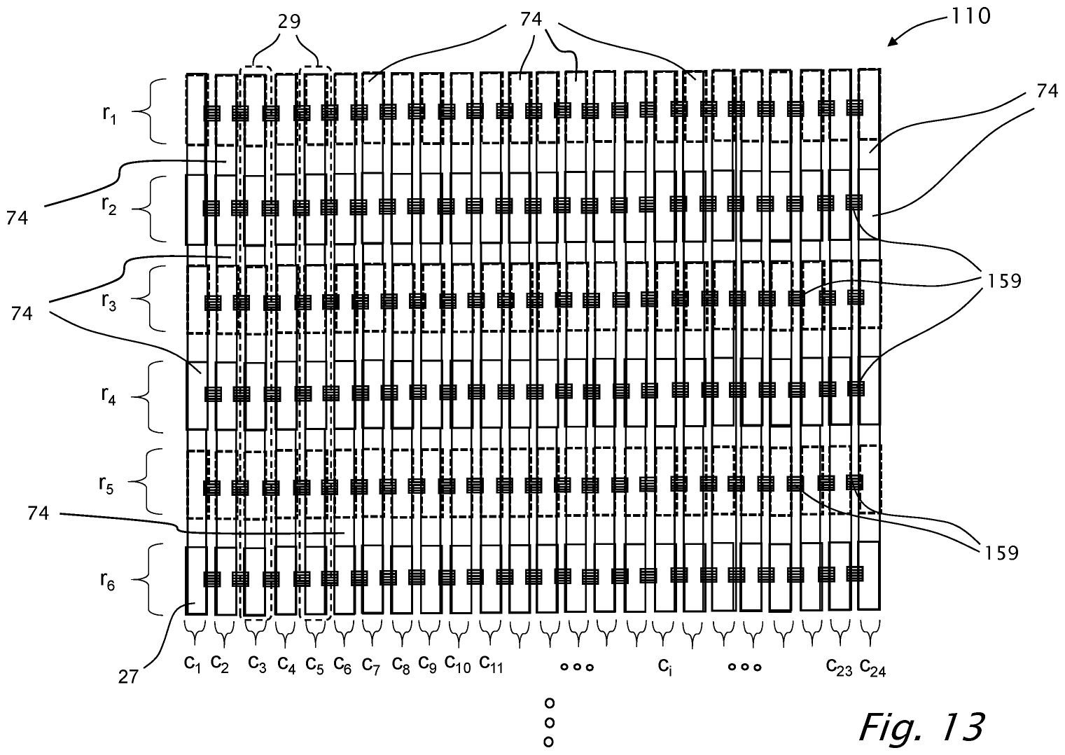

Reference is also made to FIG. 13, which similarly to example solar array 101, schematically illustrates an example solar array module 110, that includes an array configuration of solar sub-cells 27, in a 6X24 solar sub-cells matrix. Solar array module 110 includes columns (c1-c24 in this example), wherein in each column, pairs of neighboring solar sub-cells 27 are mechanically and electrically interconnected in series by a respective narrow polymer conductor segment 74 having at least one wire conductor 72 (typically, a plurality of thin wire conductors) embedded there inside, forming a string 29 of sub-cells 27. The solar sub-cells 27 in rows (r1, r2, r3, r4 r5 and r6) of solar sub-cells 27 are electrically interconnected in parallel by wire conductors 166 embedded in respective lateral short polymer conductor segments 159 (or optionally by common short common wiring segments). It should be appreciated that the wire conductors 166 embedded in lateral short polymer conductor segments 159 are conductively attached to the wire conductors 72 embedded in the narrow polymer conductor segment 74, overlapped by the respective lateral short polymer conductor segment 159, to locally form at least a partial conductive grid. In the non-limiting example shown in FIG. 13, solar array module 110 is shown in a top view illustration, wherein the short polymer conductor segments 159 in rows r1 to r6 may be conductively connected to the top, or bottom side of the respective pairs of solar cells (25, 27).

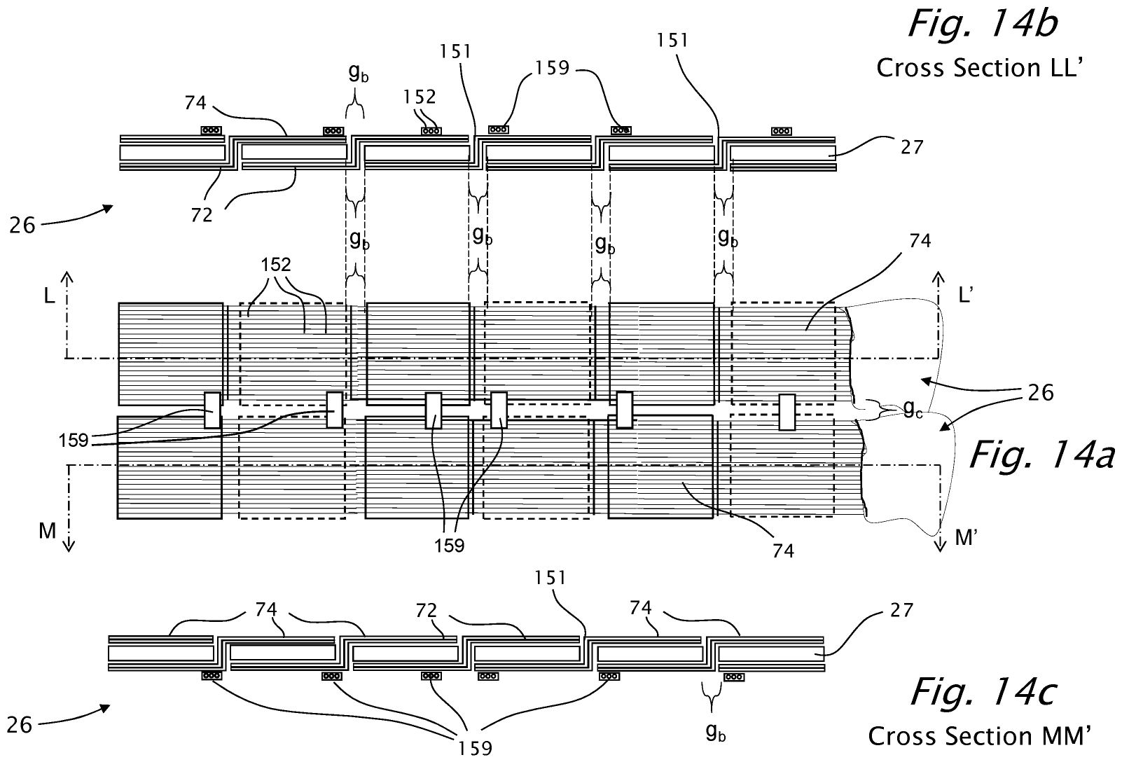

FIG. 14a schematically illustrates an example portion of a solar array matrix, showing a pair of strings 26 (or a portion thereof) of solar sub-cells 27, wherein each string 26 of sub-cells 27 is composed of pairs of solar sub-cells 27 that are electrically interconnected in series by respective narrow polymer conductor segments 74 having thin wire conductors 72 embedded there inside. Each (or some) such solar sub-cell 27 is also interconnected in parallel with its neighboring solar sub-cells 27 by an individual short polymer conductor segment 159.

It should be appreciated the when an array of sub-sells 27 only, the electric current in at module is substantially reduced compared with array of common solar cells 25. This facilitate reduction of the thickness of conductive wires, including wires embedded inside polymer conductor foils, commonly used in the industry. This may also improve the ductility of the polymer conductor foils and facilitates reduction of gaps required between cells in strings of cells.

FIGS. 14b and 14c are schematic cross section (LL′ and MM′, respectively) illustrations showing pairs of solar sub-cells 27, interconnected serially by polymer conductor stripes 150 having thin wire conductors 152. Each sub-cell 27 in row of sub-cells is parallelly interconnected by a respective short polymer conductor segment 159 (or alternatively, by a short common conductive wire) to the neighboring sub-cells 27 of the neighboring strings. The short segments of polymer conductors 159 bridges over a gap gb formed between each pair of neighboring sub-cells 27 of a string 26 of sub-cells 27, where ga>gb.

It should be appreciated that when connecting the solar cells (25, 27) of neighboring strings in parallel, the gap formed between the two neighboring sub-cells 27 of a pair of strings of solar cells (25, 27) can be minimized to gc.

In a non-limiting example, we refer back to a common solar-array module that has 60 common solar cells 25, arranged in a 6×10 matrix, and has a module surface area of ˜1.6 m2 (˜1 m×˜1.6 m) the is configured to receive the preconfigured matrix of to the common solar cells 25. The cutting of each common solar cell 25 into solar sub-cells 27 (or manufacturing such solar sub-cells), raises an issue of fitting the same module surface area that was occupied by the matrix of the common solar cells 25.

One problem is the plurality of gaps the a formed between the multiplicity of solar sub-cells 27, which plurality of the formed gaps is substantially greater than the number of gaps formed between the common solar cells 25.

It should be appreciated that a solar sub-cell, being the smaller in size and in area size with respect to a common sized PV solar cell, the solar sub-cell produces a substantially smaller electrical current, and therefore, substantially thinner conductive connecting wires can be used. For example, using the thin wire connection technology.

It should be further appreciated that since in the polymer conductor technology provide thin wire conductors 72, the narrow polymer conductor segment 74 is more ductile than the common wires common solar module wiring. Thereby, reduce the cost of the overall wiring, with respect to the wiring used with common PV cells in common solar modules.

It should be further appreciated that in crisscross matrix array with small size cells (cut sub-cells) the polymer conductor technology using thin wires, and/or smaller quantity of thin wires, facilitates bringing adjacent solar sub-cells closer together to minimize the gap formed therebetween.

Referring back to FIGS. 5 and 6, the gap formed between neighboring common solar cells 25 in a string of solar cells, using polymer conductor technology, having common wiring, forcing the gap formed between neighboring solar cells 25 to be ga. Referring back to FIGS. 14a, 14b and 14c, it is shown that the gap formed between neighboring solar sub-cells 27 in a string 26 of sub-cells, can be narrowed down to a form a gap of gb, where “ga>gb”. For example, the gap ga formed between cells of a common solar module is about 2mm, while when cutting a common solar cell 25 (15.6 cm×15.6 cm) into 5 similar stripes (15.6 cm×3.1 cm), the gap can be reduced, for example to 1 mm, and the required module surface area can be reduced accordingly.

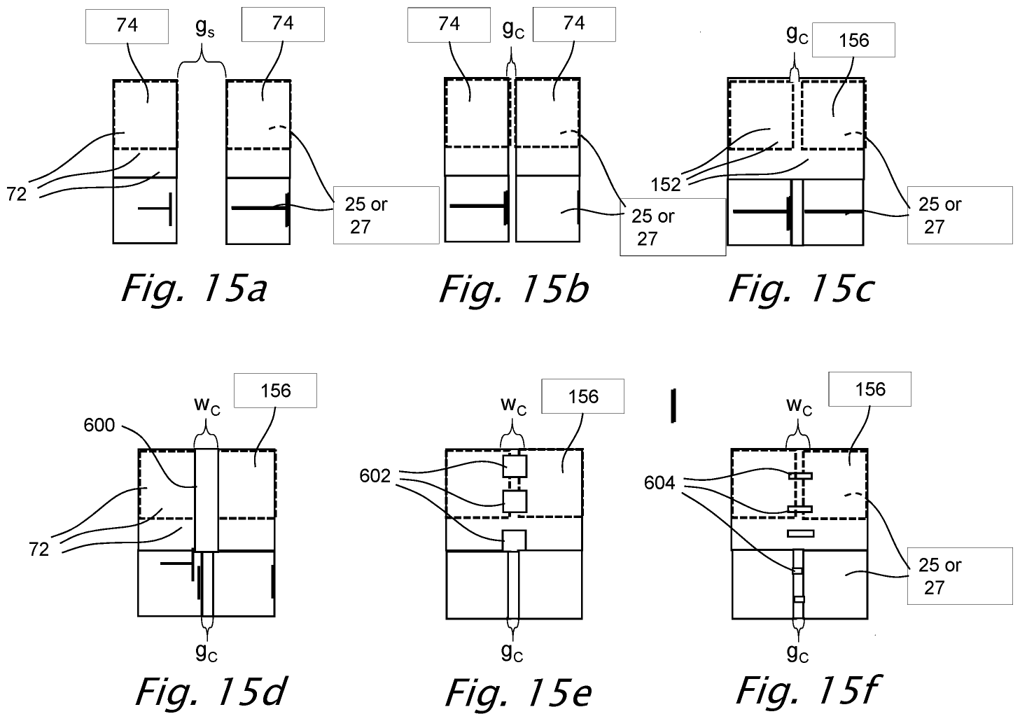

Reference is now made to FIGS. 15a-5f . FIG. 15a illustrates two solar cells (25, 27) of a pair of adjacent rows of solar cells (r1 and r2), as shown in FIG. 4a for common solar cells 25. The example singular pairs of solar cells (25, 27) are mechanically and electrically interconnected in series by respective narrow polymer conductor segments 64, and wherein the gap formed between the two pairs of solar cells (25, 27) of respective strings of common solar cells 25 or sub-cells 27, is denoted as gs. FIG. 15b illustrates two pairs of solar cells (25, 27) of a pair of adjacent strings of solar cells, wherein the example singular pairs of solar cells are mechanically and electrically interconnected in series by respective narrow polymer conductor segments 74, and wherein the gap formed between the two pairs of solar cells of a string of solar cells (25, 27) is minimized to gc.

FIG. 15c illustrates two pairs of solar cells (25, 27) of a pair of adjacent rows of sub-cells, wherein the two pairs of sub-cells are mechanically and electrically interconnected by a single wide polymer conductor stripe 156 that covers at least the two pairs of sub-cells, and wherein conductive thin wires embedded within that single wide polymer conductor stripe 156 electrically interconnects in series each of two pairs of sub-cells. The gap formed between the two pairs of sub-cells, in respective pair of rows, is also minimized to gc, wherein the polymer conductor stripe 156, having a plurality of thin wire conductors 152 embedded there inside, covers both pairs of sub-cells including over the gap gc.

FIG. 15d illustrates the two pairs of solar sub-cells 27, as shown in FIG. 15c, wherein the wide polymer conductor segment 156 further includes a wide conductor segment 600 having a width wc, where “wc >gc”, and wherein wide conductor segment 600 is configured to overlap both banks that form gap gc, to thereby bridge over gap gc, conductively. FIGS. 15e and 15f illustrate optional segmentation of wide conductor segment 600, into example wide conductor segments 602 and 604. Thereby, segment conductor 600, 602 and/or 604, respectively, facilitate electrically connecting adjacent solar cells (25, 27) of each row in parallel.

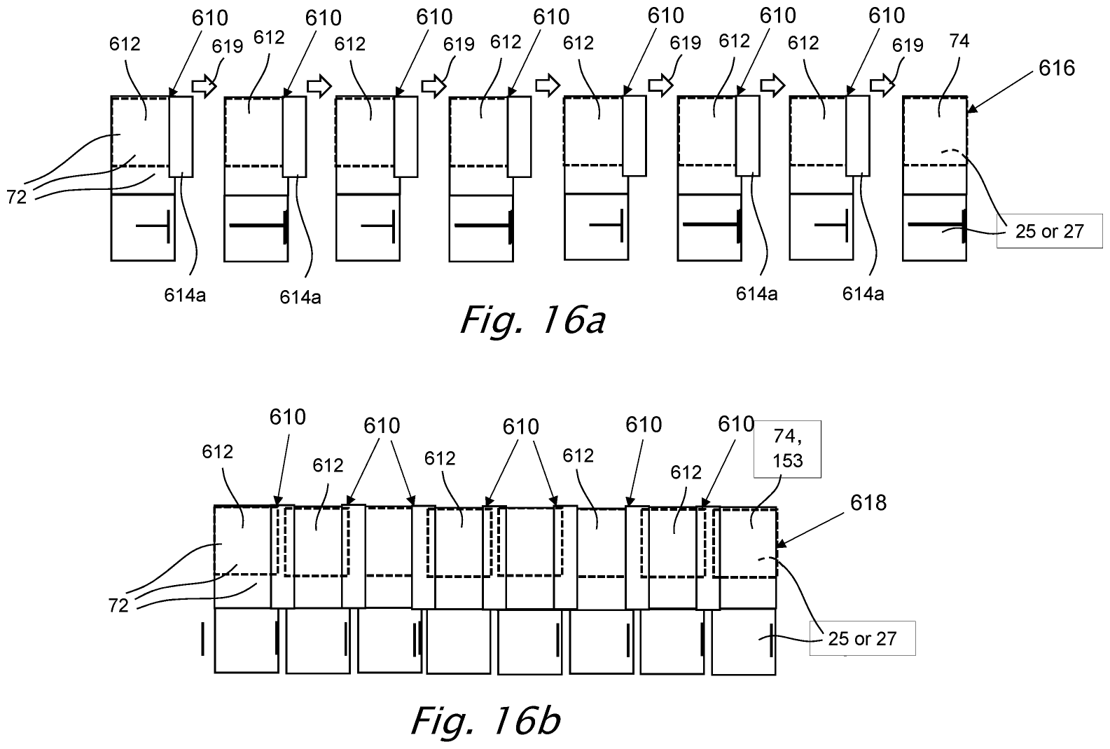

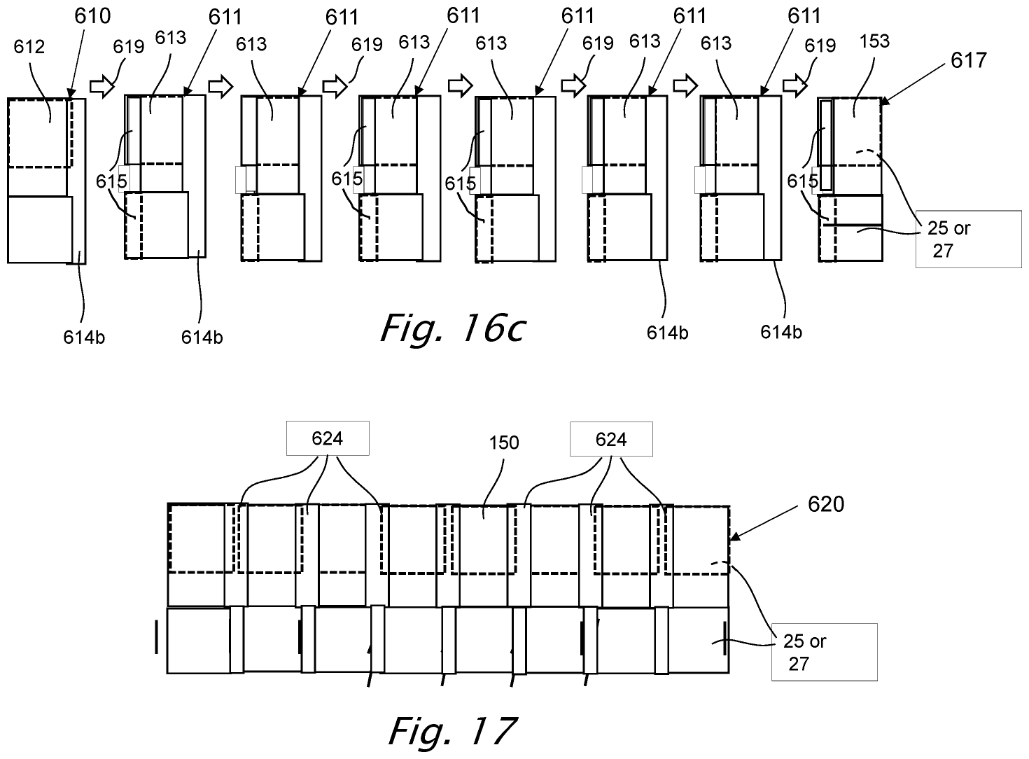

Reference is also made to FIG. 16a that illustrates two rows of pairs of solar cells (25, 27), as shown in FIGS. 15d-15f, wherein a polymer conductor segment 610 includes a polymer conductor portion 612, being similar to polymer conductor segment 156, as shown in FIG. 15a. However, polymer conductor segment 610 further includes a wide conductor wing portion 614a, being an extension wing that is similar to wide conductor segment 600 (or 602 or 604) and extends from one side of polymer conductor portion 612. The last pair 616 of solar cells (25, 27) in each pair of neighboring rows of solar cells (25, 27) remains a narrow polymer conductor 64 as shown in FIG. 15a. The wide wing conductor may be predesigned, for example, as a regular metal conductor with the same height as the height of the plurality thin wire conductors 62 of a polymer conductor segment 612, or may be predesigned as an adhesive conductive glue that facilitate conductive welding to polymer segment 612 of the neighboring solar cells (25, 27), during the regular segment welding process of polymer conductor segment 612.

During production of the solar array module, having a crisscross configuration of solar cells (25, 27), the wide conductor wing 614a is placed over the bank of the respective polymer conductor portion 612 of the adjacent solar cells (25, 27), and welded there onto. Typically, the welding is performed by heating the respective polymer conductor to a predesigned welding temperature.

FIG. 16b illustrates the pair of rows of solar cells (25, 27) after the welding step, and according to some other aspects of the present disclosure. A pair of neighboring rows of singular pairs of solar cells (25, 27) are interconnected by a single wide polymer conductor stripe 618 that mechanically and electrically interconnecting the singular pairs of neighboring sub-cells, across all relevant rows and columns of solar cells (25, 27). In one embodiment, the embedded conductive wires 62 of polymer conductor stripe 618 electrically connect each pair of singular solar cells (25, 27) in series. The wide polymer conductor stripe 618 may further includes a number of segments of wide conductor wings 614a such that when placing the wide polymer conductor stripe 618 over the singular pairs of neighboring sub-cells across all columns of sub-cells, the respective wide conductor wing 614 overlaps the side edge area of the polymer conductor portion 612 of the adjacent solar cells (25, 27) of the respective neighboring solar cells (25, 27) in each row of sub-cells, facilitating a parallel electrical connection between the solar cells (25, 27) in each row of the pair of rows. Thereby, after the welding step, the sub-cells in the rows are electrically connected in parallel by the wide wires 614a, and all solar cells (25, 27) in the respective array of solar cells (25, 27) are interconnected both serially and parallelly, that is in a crisscross configuration.

FIG. 16c is a variation of the arrangement shown in FIG. 16a, wherein, commencing with the second pair of solar cells (25, 27) in each pair of neighboring rows of solar cells (25, 27), the polymer conductor segment 611 further includes (compared to polymer conductor segment 610) a polymer conductor portion 613 that is narrower than polymer conductor portion 612, wherein a second receiving conducting wing 615 extends from the second side of polymer conductor portion 613. The second receiving conducting wing 615 allows the second bank of the respective conductive face of the solar cells (25, 27), positioned onto the polymer conductor portion 613, on two neighboring cells of two neighboring rows to receive (619) the wide conductor wing 614b of the polymer conductor portion 613 of the neighboring solar cells (25, 27). The first pair of solar cells (25, 27) in each pair of neighboring rows of solar cells (25, 27) receives a polymer conductor portion 612, as in FIG. 16a. The last pair 617 of solar cells (25, 27) in each pair of neighboring rows of solar cells (25, 27) does not include a wide conductor wing 614b but does include a second receiving conducting wing 615 that is configured to receive the wide conductor wing 614b of the preceding pair of neighboring rows of solar cells (25, 27).

During production of the solar array module, having a crisscross configuration of solar cells (25, 27), when aligning the pair of solar cells (25, 27) before the welding step of the production process, the wide conductor wing 614b is placed over (619) the exposed area 615 (a few millimeters) of the neighboring solar cells (25, 27) of the neighboring pair of solar cells (25, 27), such that in the welding step, the wide wing conductor 614b (or 614a) is conductively welded onto the second receiving conducting wing 615 of the current pair of solar cells (25, 27). After the welding step, the pair of rows of solar cells (25, 27) in each of the rows are electrically connected in parallel by the welded wide segment conductor, similar to wide stripe conductor 618.

It should be noted that at polymer conductor technology production time, by heating the respective polymer conductor to a predesigned welding temperature, the two sub-cells are welded together to thereby facilitate an electrical connection between the two sub-cells. It should be appreciated that the welding process of wide polymer conductor 600, or segment wide polymer conductor 602, 604, 614a, or 614b for parallel connection of two neighboring pairs of sub-cells is performed simultaneously with the regular welding process of the serial polymer conductors .

FIG. 17 illustrate the pair of rows of sub-cells 27 according to some other aspects of the present disclosure. A pair of neighboring rows of singular pairs of solar cells 27 are interconnected by a single wide polymer conductor stripe 620 that mechanically and electrically interconnecting the singular pairs of neighboring sub-cells 27 across all relevant rows and columns of sub-cells, in which polymer conductor stripe the embedded conductive wires electrically connect each pair of singular sub-cells in series. The wide polymer conductor stripe 620 further includes a number of segment of wide conductor wings 624 such that when placing the wide polymer conductor stripe 620 over the singular pairs of neighboring sub-cells across all columns of sub-cells, the respective wide polymer conductor stripe 624 is positioned such that it overlaps both neighboring sub-cells 27 in each row of sub-cells, facilitating a parallel electrical connection between the sub-cell 27 in each row of the pair of rows. Thereby, after the welding step, the sub-cells in the rows are electrically connected in parallel by the wide wires 624, and all sub-cell 27 in the array of sub-cell are interconnected both serially and parallelly, that is in a crisscross configuration.

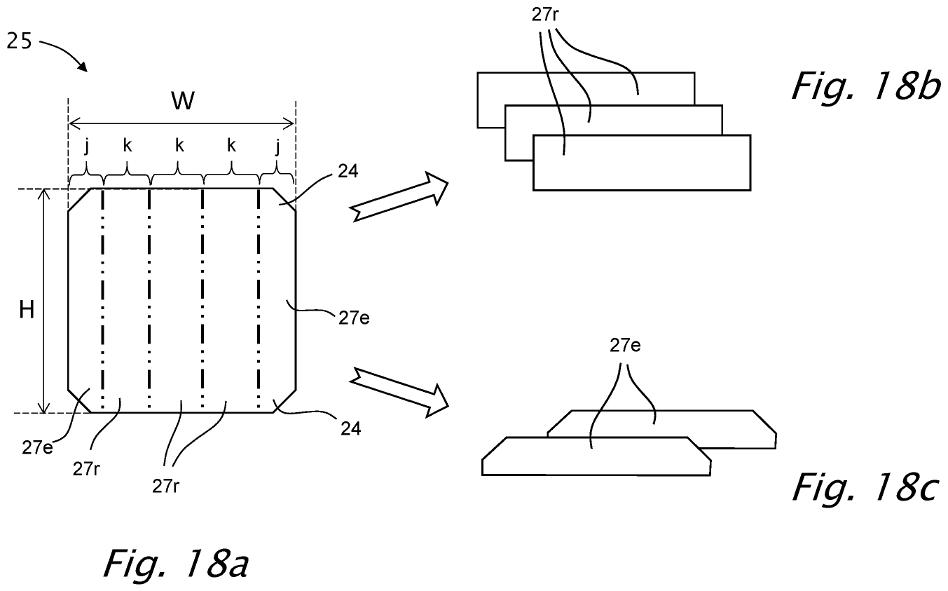

Another problem that often occurs is that in several types of solar cells 25 that are fabricated with 4 truncated corners. FIG. 18a illustrates a common size PV solar cell 25 having the dimensions HXW, where typically, a common size PV solar cell 25 has a square shape (H=W=S), where S=15.6 cm. By cutting such a common size PV solar cell 25 having 4 truncated corners, the common size PV solar cell 25 can be divided into “p” smaller sub-sells, each having the same width: j=S/p, or of different width. Since the corners 24 of a common size PV solar cell 25 may be truncated, in some embodiments, there can be of a second width size (k), where j4.

In the example shown in FIGS. 18a-18c, the common size PV solar cell 25 is subdivided into 5 sub-cells 27: 2 edge sub-cells 27e having a first size (j), and 3 inner sub-cells 27r having a second size (k). It should be appreciated that in some embodiment j=k. It should be further appreciated that there are a variety of possibilities to cut the edge sub-cell 27e and the rectangular, inner sub-cell 27r.

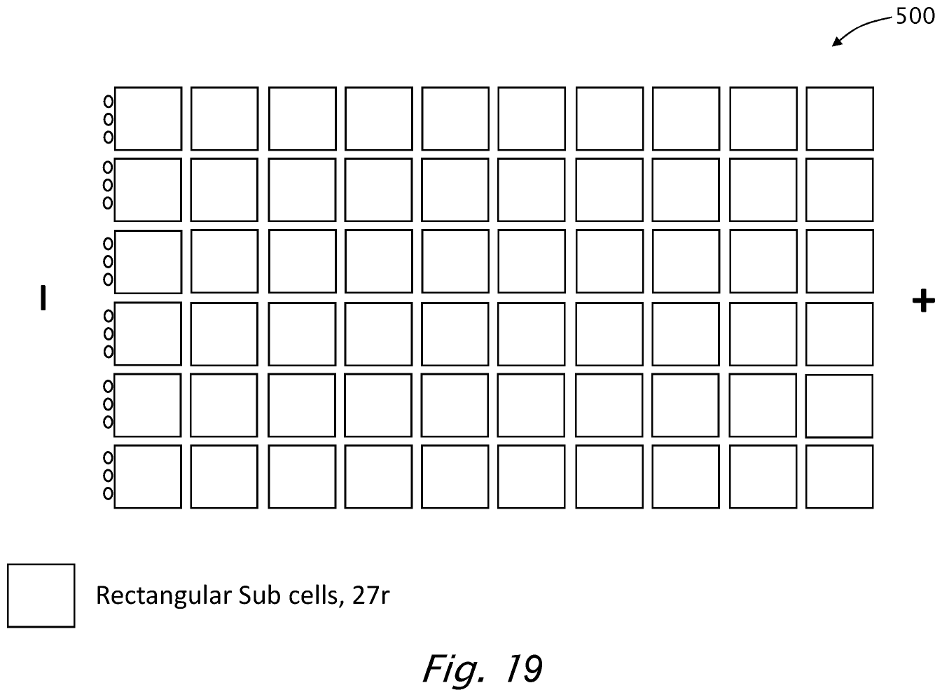

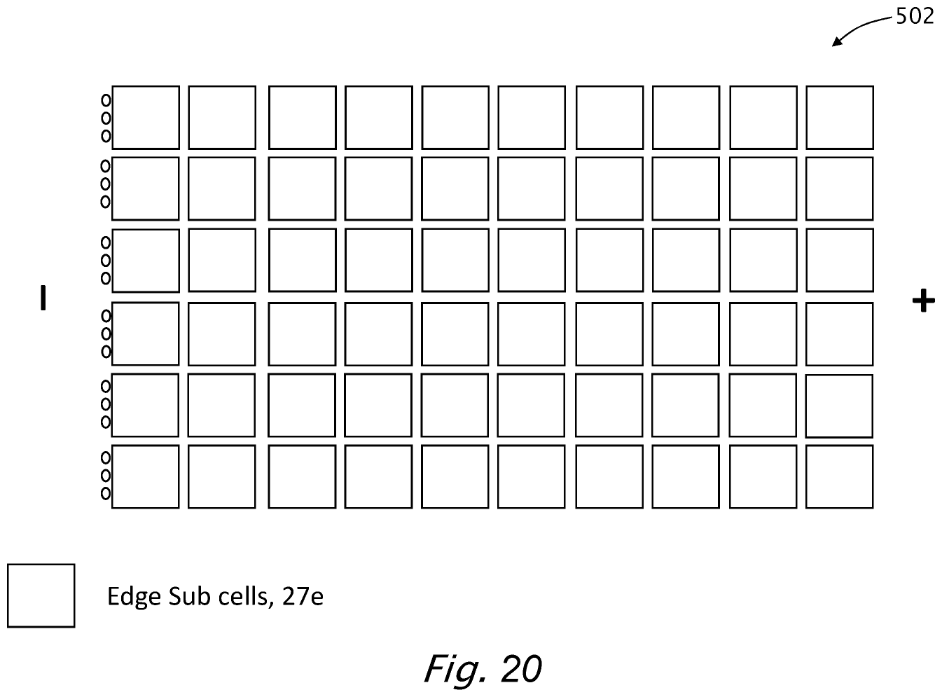

It should be further appreciated that there are a variety of possible layouts of the cut cells in a solar-cells module 500. In some embodiments solar modules are assembled from a plurality of solar sub-cells but of the same type/size (27e or 27r, in the above non-limiting example). For example, as shown in FIG. 19, the assembled module consists of only rectangular sub-cells (27r) that provides higher power yield than a solar module 502 that consists of edge sub-cells (27e) only, as shown in FIG. 20.

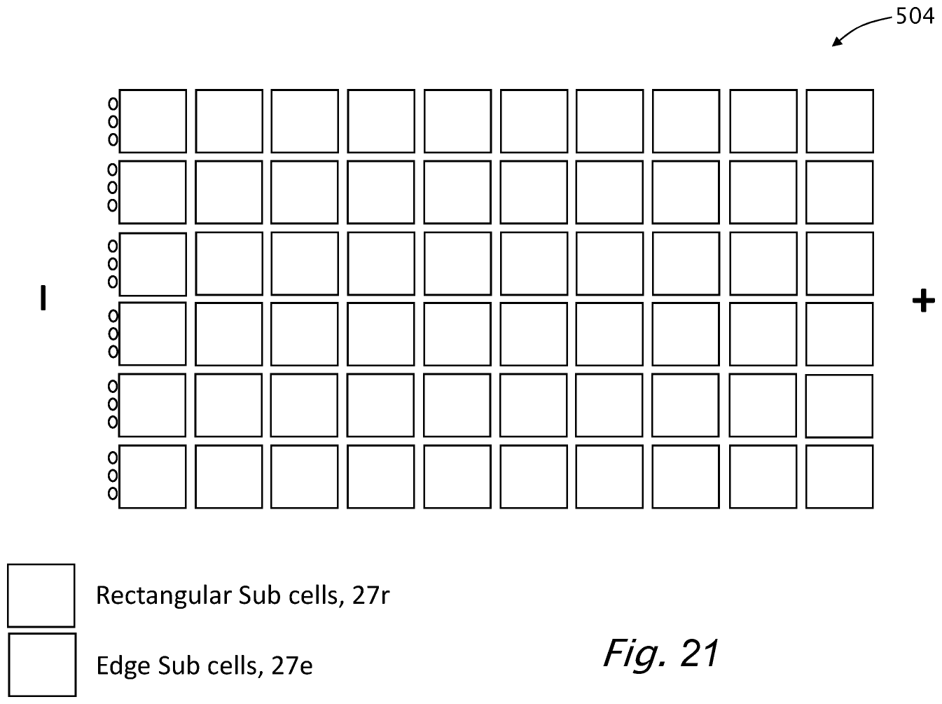

In some other embodiments, both type of solar sub-cells (27e and 27r) are combined to be mapped in a single solar module layout 504. A non-limiting example is shown in FIG. 21, combing 24 edge sub-cells 27e and 36 rectangular sub-cells 27r into a module having 60 solar sub-cells. The 60 solar sub-cells having been cut in this example from 12 common size PV solar cell 25, each common size PV solar cell yielding into 2 edge sub-cells and 3 inner sub-cells. It should be appreciated that when to combining various sized solar sub-cells into a single solar module, the smaller cells (edge sub-cell 27e in the above example) will often reduce total power output because the smaller current generation ability of the smaller cells limit the flow of the higher current generated by larger cells (rectangular sub-cell 27r in the above example). In some embodiments of the present disclosure, the solar array modules (99, 100, 101, 102, 103, 110, 200, 300, 400, 500, 502, 504) are configured to form a solar power generation module for providing operating power for a desired application.

In some embodiments of the present disclosure, the solar array modules (99, 100, 101, 102, 1 03, 110, 200, 300, 400, 500, 502, 504) are configured to form a solar power generation system for providing operating power for a desired application.

The present invention being thus described in terms of several embodiments and examples, it will be appreciated that the same may be varied in many ways. Such variations are not to be regarded as a departure from the spirit and scope of the invention, and all such modifications as would be obvious to one skilled in the art are contemplated.

1. A solar power generation module for maximizing power generated from a solar module and for minimizing the a power degradation inflicted by light obstructions, the solar power generation module comprising a plurality of common solar cells or solar sub-cells, said solar cells arranged in a physical matrix of N columns and M rows,
wherein at least one pair of neighboring rows of solar cells or solar sub-cells is mechanically and electrically interconnected by a single wide polymer conductor stripe, being a ductile conductive wiring connection technology that extends over at least two adjacent columns of said at least one pair of neighboring rows.

2. The solar power generation module as in claim 1, wherein at least one pair of neighboring solar cells, in each column of solar cells, is electrically interconnected in series by at least one respective thin wire conductors embedded inside said polymer conductor stripe.

3. The solar power generation module as in claim 2, wherein all solar cells in each pair of neighboring rows of a mutual string, are electrically interconnected in series by at least one respective thin wire conductor embedded inside said polymer conductor stripe.

4. The solar power generation module as in claim 3, wherein at least one solar cell in each string of solar cells is electrically interconnected in parallel to one or two solar cells, situated in a mutual row of an adjacent string, by a parallelly-connection conductive means.

5. The solar power generation module as in claim 4, wherein said parallelly-connection conductive means is at least one elongated common conductive wire disposed between the rows of said solar cells, across all strings, or onto said solar cells, across all strings, and wherein said elongated common conductive wire is conductively attached to the thin wire conductors to locally form at least a partial conductive grid.

6. The solar power generation module as in claim 4, wherein said parallelly-connection conductive means is at least one thin wire conductor embedded inside a single or conductively chained lateral polymer conductor cross stripe that is disposed between the rows of said solar cells, across all strings, and wherein said lateral polymer conductor cross stripe is conductively attached to the thin wire conductors to locally form at least a partial conductive grid.

7. The solar power generation module as in claim 4, wherein said parallelly-connection conductive means is at least one thin wire conductor embedded inside a stripe of a single or conductively chained lateral polymer conductor cross stripe that is disposed onto said solar cells of the at least one row of solar cells, and wherein said lateral polymer conductor cross stripe is conductively attached to the thin wire conductors to locally form at least a partial conductive grid.

8. The solar power generation module as in claim 4, wherein said parallelly-connection conductive means comprise a plurality of short conductors,
wherein each of said short conductors mechanically interconnects adjacent solar cells of adjacent strings of solar cells, and
wherein said short conductor electrically interconnected in parallel said adjacent solar cells.

9. The solar power generation module as in claim 8, wherein said short conductors are short common conductive wires or wide conductor segments.

10. The solar power generation module as in claim 8, wherein said short conductors are short lateral polymer conductor cross segments having at least one thin wire conductor embedded there inside.

11. The solar power generation module as in claim 10, wherein said solar cells are common solar cells,
wherein said parallelly-connection conductive means comprise said plurality short conductors.
wherein each of said short conductors mechanically interconnects adjacent solar cells of adjacent string of solar cells, and
wherein said short conductors electrically interconnect in parallel said adjacent solar cells.

12. The solar power generation module as in claim 10, wherein said solar cells are solar cells,
wherein each pair of solar cells in each column, is electrically interconnected in series by the thin wire conductors embedded inside a narrow polymer conductor stripe, instead of said single wide polymer conductor stripe.

13. The solar power generation module as in claim 10, wherein said solar cells are solar cells,
wherein each pair of solar cells in each column, is electrically interconnected in series of by the thin wire conductors embedded inside a wide polymer conductor stripe.

14. The solar power generation module as in claim 8, wherein said solar cells are solar sub-cells, and
wherein each pair of solar sub-cells in each column, is electrically interconnected in series of by the thin wire conductors embedded inside a narrow polymer conductor stripe, instead of said single wide polymer conductor stripe.

15. The solar power generation module as in claim 8,
wherein a minimum gap formed in string of solar cells between adjacent common solar cells is ga, being limited by a thickness and ductility of the thin wire conductors embedded inside a common polymer conductor stripe used in common solar modules polymer stripe wiring, and
wherein a minimum gap gb formed in a string of solar cells between adjacent solar sub-cells that are mechanically and electrically interconnected in series by said polymer conductor stripe, said polymer conductor stripe comprising thinner embedded wires and being more ductile than a common polymer conductor stripe segment, thereby facilitating narrowing gap gb, such that ga>gb.

16. The solar power generation module as in claim 8, wherein a gap gc formed between each of said adjacent solar cells of adjacent strings of solar cells can be minimized, said adjacent solar cells being electrically interconnected in parallel, wherein gap gc is mechanically and electrically bridged by said short conductors, and wherein said short conductors are selected from a group of conductors including:
a short polymer conductor segment having at least one thin wire conductor embedded there inside;
a single polymer conductor stripe having at least one wide conductor segment embedded there inside;
a polymer conductor segment comprising: a) a polymer conductor portion configured to mechanically and electrically interconnect in series one pair of solar cells of adjacent pair of rows of solar cells; and b) a wide conductor wing portion extending from one predesigned side of said polymer conductor segment, being said short conductor, and wherein said wide conductor wing portion is configured to be conductively attached to the polymer conductor portion of next adjacent polymer conductor segment of the next pair of solar cells of said adjacent pair of rows;
a polymer conductor segment comprising: a) a polymer conductor portion configured to mechanically and electrically interconnect in series one pair of solar cells of adjacent pair of rows of solar cells; b) a wide conductor wing portion extending from one predesigned side of said polymer conductor portion, said wide conductor wing portion being said short conductor; and c) a second receiving conducting wing extending from the second side of said polymer conductor portion, wherein said wide conductor wing portion is configured to be conductively attached to the second receiving conducting wing of next adjacent polymer conductor segment of the next pair of solar cells of said adjacent pair of rows; and
a single wide polymer conductor stripe that extends over at least two adjacent columns of said at least one pair of adjacent rows, including the gap gc formed there between said at least two adjacent columns, said single wide polymer conductor stripe comprising: a) a polymer conductor segment configured to mechanically and electrically interconnect in series each pair of solar cells of said adjacent pair of rows; and b) a wide conductor wing portion, wherein said wide conductor wing portion is configured to bridge over said gc and thereby electrically connect the respective pair of solar cells, of said at least two adjacent columns, in parallel.

17. The solar power generation module as in claim 16, wherein said conductive attachment of said wide conductor wing portion to said polymer conductor portion of next adjacent polymer conductor segment of the next pair of solar cells of said adjacent pair of rows is performed by a welding step.

18. The solar power generation module as in claim 16, wherein said conductive attachment of said wide conductor wing portion to said second receiving conducting wing of next adjacent polymer conductor segment of the next pair of solar cells of said adjacent pair of rows is performed by a welding step.

19. The solar power generation module as in claim 17, wherein said welding step includes heating to a melting temperature.

20. The solar power generation module as in claim 16, wherein said conductivity of said wide conductors is attained by using conductive metal or by an adhesive conductive glue.

21. A solar array module including the solar power generation module as in claim 15 having a common surface area preconfigured to accommodate a matrix of common solar cells interspaced by said gaps ga and gs, the solar array module, being reconfigured to accommodate a matrix of solar sub-cells, the solar array module further comprising a plurality of solar sub-cells electrically interconnected in a crisscross matrix, wherein at least a majority of said plurality of solar sub-cells are interspaced, respectively, by said gaps gb and gc.

22. The solar array module as in claim 21, wherein all said solar sub-cells have rectangular shape and essentially of equal dimensions.

23. The solar array module as in claim 21, wherein said solar sub-cells were cut from generally square common solar cells fabricated with 4 truncated corners, and wherein the cut sub-cells include two edge sub-cell, each having two truncated corners, and at least one rectangular, inner sub-cell.

24. The solar array module as in claim 23, wherein the cut solar sub-cells further include at least one rectangular, inner sub-cell.

25. The solar array module as in claim 24, wherein said cut solar sub-cells are sorted into groups of solar sub-cells, each group having essentially equal dimensions.

26. The solar array module as in claim 25, wherein the accommodated matrix of solar sub-cells are essentially of equal dimensions.

27. The solar array module as in claim 25, wherein the accommodated matrix of solar sub-cells have mixed dimensions.
